(19) United States
(12) Patent Application Publication
(10) Pub. No.: US 2024/0373752 A1
(43) Pub. Date: Nov. 7, 2024

(54) SEMICONDUCTOR SUBSTRATE AND PACKAGE STRUCTURE INCLUDING THE SAME

(71) Applicant: Advanced Semiconductor Engineering, Inc., Kaohsiung (TW)

(72) Inventors: Cheng-Ting CHEN, Kaohsiung (TW); Hung-Yi LIN, Kaohsiung (TW); Cheng-Yuan KUNG, Kaohsiung (TW)

(73) Assignee: Advanced Semiconductor Engineering, Inc., Kaohsiung (TW)

(21) Appl. No.: 18/144,163

(22) Filed: May 5, 2023

(51) Int. Cl. H10N 30/00; H10N 30/20; H10N 30/87

(52) U.S. Cl. CPC H10N 30/706; H10N 30/20; H10N 30/874

(57) ABSTRACT

A semiconductor substrate and a package structure including the same are provided. The semiconductor substrate includes a first surface and a second surface. The first surface includes a filtering region. The second surface is opposite to the first surface and includes an amplifying region.

### BACKGROUND

### 1. Field of the Disclosure

The present disclosure relates to a semiconductor substrate and a package structure including the same.

### 2. Description of the Related Art

Along with the rapid development in electronics industry and the progress of semiconductor processing technologies, semiconductor packages are integrated with an increasing number of electronic devices to achieve improved electrical performance and additional functions. To manufacture semiconductor packages including semiconductor chips with an increasing number of I/O connections, sizes of the semiconductor chips and the semiconductor packages may correspondingly increase. Thus, a cost may correspondingly increase. Alternatively, to minimize sizes of semiconductor packages including semiconductor chips with an increasing number of I/O connections, a bonding pad density of semiconductor substrates used for carrying the semiconductor chips should correspondingly increase.

### SUMMARY

In some embodiments, a semiconductor substrate includes a first surface and a second surface. The first surface includes a filtering region. The second surface is opposite to the first surface and includes an amplifying region.

In some embodiments, a package structure includes a semiconductor substrate, a filter structure and an amplifier. The semiconductor substrate has a first surface and a second surface opposite to the first surface. The filter structure is disposed adjacent to the first surface. The amplifier is disposed under the second surface.

In some embodiments, a package structure includes a semiconductor substrate and a piezoelectric material. The semiconductor substrate defines a cavity. The piezoelectric material is disposed over the cavity of the semiconductor substrate. The cavity is coupled to the piezoelectric material and configured to reflect an acoustic wave.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of a package structure according to some embodiments of the present disclosure.

FIG. 2 illustrates an enlarged view of an area “A” shown in FIG. 1.

FIG. 3 illustrates an enlarged view of an area “B” shown in FIG. 1.

FIG. 4 illustrates a bottom view of the first filter structure of FIG. 1, wherein an insulation layer is omitted for the purpose of the clear explanation.

FIG. 5 illustrates an enlarged view of an area “C” shown in FIG. 4.

FIG. 6 illustrates a cross-sectional view of a package structure according to some embodiments of the present disclosure.

FIG. 6A illustrates a top view of an inductor of FIG. 6.

FIG. 6B illustrates a cross-sectional view of a package structure according to some embodiments of the present disclosure.

FIG. 7 illustrates a cross-sectional view of an assembly structure according to some embodiments of the present disclosure.

FIG. 7A illustrates a cross-sectional view of an assembly structure according to some embodiments of the present disclosure.

FIG. 8 illustrates a cross-sectional view of a package structure according to some embodiments of the present disclosure.

FIG. 9 illustrates a cross-sectional view of a package structure according to some embodiments of the present disclosure.

FIG. 10 illustrates a cross-sectional view of a package structure according to some embodiments of the present disclosure.

FIG. 11 illustrates one or more stages of an example of a method for manufacturing a package structure according to some embodiments of the present disclosure.

FIG. 12 illustrates one or more stages of an example of a method for manufacturing a package structure according to some embodiments of the present disclosure.

FIG. 13 illustrates one or more stages of an example of a method for manufacturing a package structure according to some embodiments of the present disclosure.

FIG. 14 illustrates one or more stages of an example of a method for manufacturing a package structure according to some embodiments of the present disclosure.

FIG. 15 illustrates one or more stages of an example of a method for manufacturing a package structure according to some embodiments of the present disclosure.

FIG. 16 illustrates one or more stages of an example of a method for manufacturing a package structure according to some embodiments of the present disclosure.

FIG. 17 illustrates one or more stages of an example of a method for manufacturing a package structure according to some embodiments of the present disclosure.

FIG. 18 illustrates one or more stages of an example of a method for manufacturing a package structure according to some embodiments of the present disclosure.

FIG. 19 illustrates one or more stages of an example of a method for manufacturing a package structure according to some embodiments of the present disclosure.

FIG. 20 illustrates one or more stages of an example of a method for manufacturing a package structure according to some embodiments of the present disclosure.

FIG. 21 illustrates one or more stages of an example of a method for manufacturing a package structure according to some embodiments of the present disclosure.

FIG. 22 illustrates one or more stages of an example of a method for manufacturing a package structure according to some embodiments of the present disclosure.

FIG. 23 illustrates one or more stages of an example of a method for manufacturing a package structure according to some embodiments of the present disclosure.

FIG. 24 illustrates one or more stages of an example of a method for manufacturing a package structure according to some embodiments of the present disclosure.

FIG. 25 illustrates one or more stages of an example of a method for manufacturing a package structure according to some embodiments of the present disclosure.

FIG. 26 illustrates one or more stages of an example of a method for manufacturing a package structure according to some embodiments of the present disclosure.

FIG. 27 illustrates one or more stages of an example of a method for manufacturing a package structure according to some embodiments of the present disclosure.

FIG. 28 illustrates one or more stages of an example of a method for manufacturing a package structure according to some embodiments of the present disclosure.

FIG. 29 illustrates one or more stages of an example of a method for manufacturing a package structure according to some embodiments of the present disclosure.

FIG. 30 illustrates one or more stages of an example of a method for manufacturing a package structure according to some embodiments of the present disclosure.

FIG. 31 illustrates one or more stages of an example of a method for manufacturing a package structure according to some embodiments of the present disclosure.

FIG. 32 illustrates a cross-sectional view of a package structure according to some embodiments of the present disclosure.

FIG. 33 illustrates a cross-sectional view of a package structure according to some embodiments of the present disclosure.

FIG. 34 illustrates a cross-sectional view of a package structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

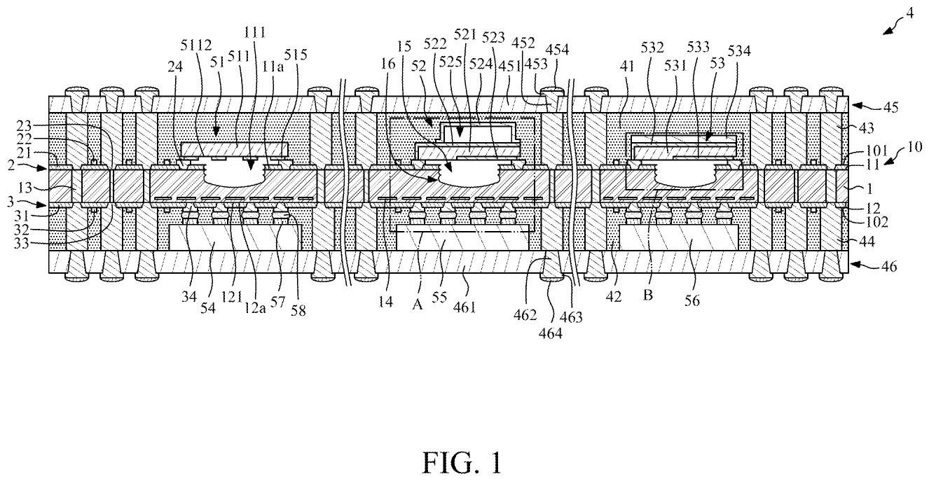

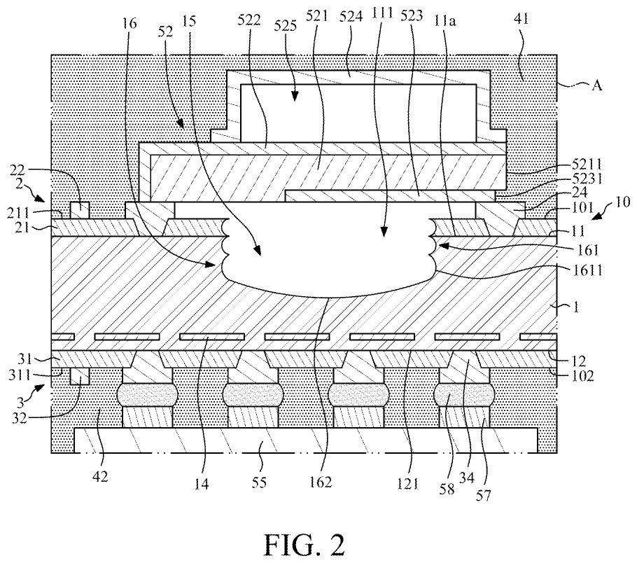

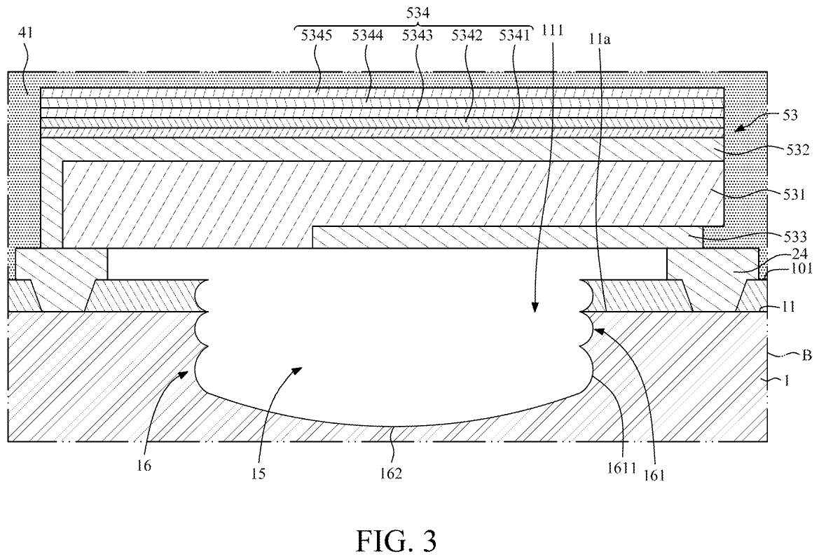

FIG. 1 illustrates a cross-sectional view of a package structure 4 according to some embodiments of the present disclosure. FIG. 2 illustrates an enlarged view of an area “A” shown in FIG. 1. FIG. 3 illustrates an enlarged view of an area “B” shown in FIG. 1. The package structure 4 may include a semiconductor substrate structure 10, at least one filter structure 51, 52, 53, at least one amplifier 54, 55, 56, a plurality of first pillars 43, a first encapsulant 41, a plurality of second pillars 44, a second encapsulant 42, a third redistribution structure 45, a plurality of first solders 454, a fourth redistribution structure 46, a plurality of second solders 464.

The semiconductor substrate structure 10 may be a RFIC (Radio-Frequency Integrated Circuit) substrate structure. The semiconductor substrate structure 10 may have a first surface 101 (e.g., a top surface) and a second surface 102 (e.g., a bottom surface) opposite to the first surface 101. The semiconductor substrate structure 10 may include a semiconductor substrate 1, a first redistribution structure 2 and a second redistribution structure 3. The semiconductor substrate 1 may have a first surface 11 and a second surface 12 opposite to the first surface 11. The semiconductor substrate 1 may include an active circuit layer 14 in the semiconductor substrate 1 and disposed adjacent to the second surface 12. Thus, the second surface 12 may be an active surface. The active circuit layer 14 of the semiconductor substrate 1 may operate in a frequency band of 300 KHz to 300 GHz. For example, the operation frequency of the semiconductor substrate 1 may be in a range of 300 KHz to 300 GHz. Thus, the semiconductor substrate 1 may be a RFIC (Radio-Frequency Integrated Circuit) substrate. The semiconductor substrate 1 may be included in an antenna switch module (ASM), an envelope tracker, a switch (S/W) and an antenna tuner, etc. In some embodiments, the first surface 11 of the semiconductor substrate 1 may include a first portion 11a. The first portion 11a may define a filtering region 111 configured to filter a signal. Thus, the first surface 11 may include the filtering region 111. The second surface 12 of the semiconductor substrate 1 may include a second portion 12a. The second portion 12a may define an amplifying region 121 configured to amplify a signal. Thus, the second surface 12 may include the amplifying region 121. The active circuit layer 14 may be closer to the amplifying region 121 than to the filtering region 111.

In some embodiments, the semiconductor substrate structure 10 or the semiconductor substrate 1 may include at least one first acoustic impedance structure 15 on the first surface 11 of the semiconductor substrate 1 or the first surface 101 of the semiconductor substrate structure 10. In some embodiments, the first acoustic impedance structure 15 may include a cavity 15 in the semiconductor substrate 1. For example, the cavity 15 may be defined by a groove 16 or a recess portion 16 recessed from the first surface 11 of the semiconductor substrate 1 or the first surface 101 of the semiconductor substrate structure 10. That is, the semiconductor substrate 1 or the semiconductor substrate structure 10 may define a groove 16 or a recess portion 16 to form the cavity 15. Alternatively, the semiconductor substrate 1 may define the cavity 15. The cavity 15 may be recessed from the first surface 11 (e.g., the top surface) of the semiconductor substrate 1 or the first surface 101 of the semiconductor substrate structure 10. The semiconductor substrate 1 may include the cavity 15 located adjacent to the filtering region 111. The active circuit layer 14 of the semiconductor substrate 1 is located under the cavity 15. The air in the cavity 15 has a relatively low acoustic impedance of about 400 kg/m²s.

The first redistribution structure 2 may be disposed on the first surface 11 of the semiconductor substrate 1. In some embodiments, the first redistribution structure 2 may include a first dielectric structure 21 and a first conductive structure 22. The first dielectric structure 21 may include at least one first dielectric layer. A material of the first dielectric layer may include an insulating material, a passivation material, a dielectric material or a solder resist material, such as, for example, a benzocyclobutene (BCB) based polymer or a polyimide (PI). In some embodiments, the first dielectric layer may include a cured photoimageable dielectric (PID) material, such as an epoxy or a PI including photoinitiators. The first conductive structure 22 may include at least one first redistribution layer (RDL), at least one first via 23 and at least one first protrusion pad 24. The first redistribution layer (RDL) may be disposed on the first dielectric layer, or may be embedded in the first dielectric structure 21. The first via 23 may extend through the first dielectric layer. The first protrusion pad 24 may extend through the first dielectric layer, and may be exposed from a top surface 211 (FIG. 2) of the first dielectric structure 21. The top surface 211 of the first dielectric structure 21 may be the first surface 101 of the semiconductor substrate structure 10.

The second redistribution structure 3 may be disposed on the second surface 12 of the semiconductor substrate 1. In some embodiments, the second redistribution structure 3 may include a second dielectric structure 31 and a second conductive structure 32. The second dielectric structure 31 may include at least one first dielectric layer. The second conductive structure 32 may include at least one second redistribution layer (RDL), at least one second via 33 and at least one second protrusion pad 34. The second redistribution layer (RDL) may be disposed on the second dielectric layer, or may be embedded in the second dielectric structure 31. The second via 33 may extend through the second dielectric layer. The second protrusion pad 34 may extend through the second dielectric layer, and may be exposed from a bottom surface 311 (FIG. 2) of the second dielectric structure 31. The bottom surface 311 of the second dielectric structure 31 may be the second surface 102 of the semiconductor substrate structure 10.

The semiconductor substrate 1 may include a plurality of through vias 13 extending through the semiconductor substrate 1 and configured to transmit a signal from the filtering region 111 to the amplifying region 121. That is, the through vias 13 may extend between the first surface 11 of the semiconductor substrate 1 and the second surface 12 of the semiconductor substrate 1 so as to electrically connect the first surface 11 of the semiconductor substrate 1 and the second surface 12 of the semiconductor substrate 1. The first via 23 and the second via 33 may electrically connect to the through via 13. Thus, the through vias 13 may electrically connect the first conductive structure 22 of the first redistribution structure 2 and the second conductive structure 32 of the second redistribution structure 3. Thus, the first redistribution structure 2 and the second redistribution structure 3 disposed at opposite sides of the semiconductor substrate 1 may be electrically connected to each other through the through vias 13. In some embodiments, the through vias 13 may not have a consistent width. The width of some of the through vias 13 may be greater than or less than the width of another through vias 13. The width of the through via 13 may be greater than, equal to or less than a width of the opening of the first dielectric layer of the first dielectric structure 21 or a width of the opening of the second dielectric layer of the second dielectric structure 31. A width of the first via 23 and a width of the second via 33 may be greater than, less than or equal to a width of the through via 13. In some embodiments, the through vias 13 may be disposed around the cavity 15.

As shown in FIG. 2, the recess portion 16 or the groove 16 may have an inner lateral surface 161 and a bottom wall 162. Thus, the semiconductor substrate 1 may include the inner lateral surface 161 defining the cavity 15. The inner lateral surface 161 may include at least one curved surface 1611 (e.g., horizontal concave surfaces). In some embodiments, the inner lateral surface 161 may include a plurality of curved surfaces 1611 stacked along a direction nonparallel with the first surface 11 of the semiconductor substrate 1. The inner lateral surface 161 may be not a flat surface. In addition, the bottom wall 162 may include a curved surface in a cross section. The bottom wall 162 may be not a flat surface. The bottom wall 162 may include a vertical concave surface. Further, the recess portion 16 or the groove 16 may extend through the first redistribution structure 2. The recess portion 16 or the groove 16 may not extend through the semiconductor substrate 1 or the semiconductor substrate structure 10. The cavity 15 defined by the recess portion 16 or the groove 16 is located in the filtering region 111 of the first surface 11 of the semiconductor substrate 1 or the semiconductor substrate structure 10. A bottom end of the cavity 15 (e.g., the bottom wall 162 of the recess portion 16) may be closer to the active circuit layer 14 than the first surface 11 of the semiconductor substrate 1 is. The bottom end of the cavity 15 may be closer to the second surface 12 of the semiconductor substrate 1 than to the first surface 11 of the semiconductor substrate 1. Thus, the active circuit layer 14 may be located between the recess portion 16 or the cavity 15 and the second surface 12 of the semiconductor substrate 1.

The filter structure 51, 52, 53 may be a transducer device. The filter structure 51, 52, 53 may be configured to receive a force signal. For example, the filter structure 51, 52, 53 may include the first acoustic impedance structure 15 and a main body 511, 521, 531 (e.g., a piezoelectric material 511, 521, 531). The piezoelectric material 511, 521, 531 may be disposed over the cavity 15. The piezoelectric material 511, 521, 531 may be disposed over the first surface 11 (e.g., the top surface) of the semiconductor substrate 1. The piezoelectric materials 511, 512, 513 may have a direct piezoelectric effect that is the ability to generate an electric dipole moment in response to an applied stress or force. The electric dipole moment may be defined as a charged body (such as LiTaO₃/LiNbO₃/AlN/ZnO, etc.) that can be charged by an external force. The piezoelectric materials 511, 512, 513 may be applied in different acoustic passive components that can convert electrical signals into mechanical energy and then convert the mechanical energy into electrical signals. Such acoustic passive components may be band-pass filter, low-pass filter, high-pass filter, band-stop filter, etc. The operating frequency of such acoustic passive components may be in a range of 300 MHz to 6 GHz. The filter structure 51, 52, 53 may be disposed adjacent to the first surface 11 of the semiconductor substrate 1. The filter structure 51, 52, 53 may be disposed over and/or electrically connected to the filtering region 111 of the first surface 11 of the semiconductor substrate 1. In some embodiments, the filter structure 51, 52, 53 may be attached to and/or electrically connected to the first redistribution structure 2 of the semiconductor substrate structure 10. The recess portion 16 or the cavity 15 may be included in the filter structure 51, 52, 53. The cavity 15 may be coupled to the piezoelectric material 511, 521, 531, and may be configured to reflect an acoustic wave. The cavity 15 may be configured to reflect an oscillating wave generated by the piezoelectric material 511, 521, 531. The cavity 15 and the piezoelectric material 511 521, 531 constitute a filter structure.

During operation, the acoustic wave may oscillate in the piezoelectric material 511, 521, 531 to form a standing wave. Since the air in the cavity 15 has a relatively low acoustic impedance, and the ratio of the acoustic impedance of the piezoelectric material 511, 521, 531 to the acoustic impedance of the air in the cavity 15 may be about 10000, thus, most of the acoustic wave energy will be reflected back to the piezoelectric material 511, 521, 531 at the boundary between the piezoelectric material 511, 521, 531 and the air in the cavity 15. For example, a total reflection may occur at such boundary. Thus, the reflected acoustic wave and the original acoustic wave (i.e., the incident acoustic wave) will form a standing wave, so as to obtain the minimum insertion loss and the maximum Q value. That is, the air in the cavity 15 may confine or retain the acoustic energy in the piezoelectric material 511, 521, 531.

In some embodiments, the main body 511, 521, 531 (e.g., the piezoelectric material 511, 521, 531) may be configured to generate an acoustic wave. A boundary may be formed between the main body 511, 521, 531 (e.g., the piezoelectric material 511, 521, 531) and the first acoustic impedance structure 15 (e.g., the cavity 15). A first acoustic reflectivity of the acoustic wave at the boundary may be greater than 0.5. In some embodiments, the first acoustic reflectivity may be substantially equal to 1.

Further, the recess portion 16 or the cavity 15 may be located under the piezoelectric material 511, 521, 531 of the filter structure 51, 52, 53. The recess portion 16 or the cavity 15 may be configured to reduce a heat that comes from the semiconductor substrate 1 and enters the piezoelectric material 511, 521, 531 of the filter structure 51, 52, 53. For example, the air in the recess portion 16 or the cavity 15 may have a relatively low thermal conductivity coefficient of about 0.024 W/m·K, and may be a thermal barrier that can reduce an amount of heat that is generated by the active circuit layer 14 and transferred to the piezoelectric material 511, 521, 531 of filter structure 51, 52, 53 by heat convection.

In addition, the recess portion 16 or the cavity 15 may be configured to inhibit a delamination between the filter structure 51, 52, 53 and the semiconductor substrate 1 (or the semiconductor substrate structure 10). Alternatively, the recess portion 16 or the cavity 15 may be a stress buffer structure that can be capable of absorbing stress in the semiconductor substrate 1 so as to reduce a risk that the piezoelectric material 511, 521, 531 of filter structure 51, 52, 53 detaches from the semiconductor substrate 1 (or the semiconductor substrate structure 10). In some embodiments, a coefficient of thermal expansion (CTE) of the semiconductor substrate 1 is different from a CTE of the first redistribution structure 2 and a CTE of the second redistribution structure 3. For example, the CTE of the semiconductor substrate 1 may be greater than the CTE of the first redistribution structure 2 and the CTE of the second redistribution structure 3. Thus, a delamination between the piezoelectric materials 511, 521, 531 of the filter structure 51, 52, 53 and the semiconductor substrate 1 (or the semiconductor substrate structure 10) may occur readily due to thermal stress generated during or after one or more thermal cycles. However, the recess portion 16 or the cavity 15 may absorb a portion of such thermal stress, and may be configured to inhibit a delamination between the semiconductor substrate 1 and the first redistribution structure 2.

The amplifier 54, 55, 56 may include a low noise amplifier (LNA) and/or a power amplifier (PA). The amplifier 54, 55, 56 may be disposed under the second surface 12 of the semiconductor substrate 1. The amplifier 54, 55, 56 may be disposed over and/or electrically connected to the amplifying region 121 of the second surface 12 of the semiconductor substrate 1. In some embodiments, the amplifier 54, 55, 56 may be attached to and/or electrically connected to the second redistribution structure 3 of the semiconductor substrate structure 10. Thus, the filter structure 51, 52, 53 and the amplifier 54, 55, 56 are disposed at opposite sides of the semiconductor substrate 1 (or the semiconductor substrate structure 10), and may be electrically connected to each other through the semiconductor substrate 1 (or the semiconductor substrate structure 10). The recess portion 16 or the cavity 15 may be located between the piezoelectric material 511, 521, 531 of the filter structure 51, 52, 53 and the amplifier 54, 55, 56. The semiconductor substrate 1 may be a double sided IC and can provide optimized line density and line width. The resistance of the chip signal transmission path and the power supply path becomes smaller, and the interference also becomes smaller.

As shown in FIG. 2, a vertical projection of the filter structure 51, 52, 53 may overlap a vertical projection of the amplifier 54, 55, 56. For example, the vertical projection of the filter structure 51, 52, 53 may be located within the vertical projection of the amplifier 54, 55, 56. In addition, a width of the recess portion 16 or the cavity 15 may be less than a width of the piezoelectric material 511, 521, 531 of the filter structure 51, 52, 53 and a width of the amplifier 54, 55, 56. Thus, a vertical projection of the recess portion 16 or the cavity 15 may be located within the vertical projection of the piezoelectric material 511, 521, 531 of the filter structure 51, 52, 53 and the vertical projection of the amplifier 54, 55, 56. In some embodiments, the amplifier 54, 55, 56 may include a semiconductor material having an energy gap greater than an energy gap of the semiconductor substrate 1. For example, the material of the amplifier 54, 55, 56 may be selected from a group consisting of SiC, GaN, GaAs, and other group III-V material or group II-VI material.

In some embodiments, the filter structure 51, 52, 53 may include a first filter structure 51, a second filter structure 52 and a third filter structure 53. The amplifier 54, 55, 56 may include a first amplifier 54, a second amplifier 55 and a third amplifier 56. The first filter structure 51 may be disposed over the first amplifier 54. The second filter structure 52 may be disposed over the second amplifier 55. The third filter structure 53 may be disposed over the third amplifier 56.

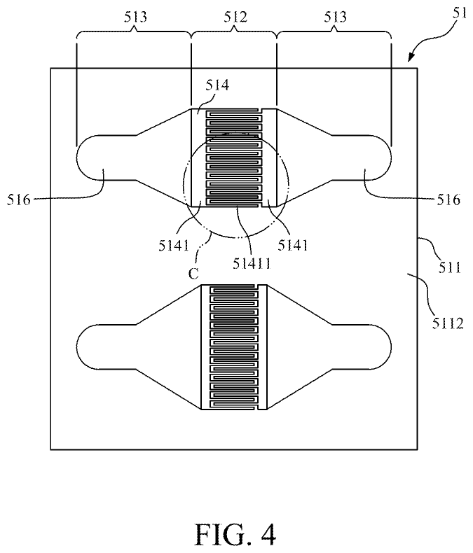

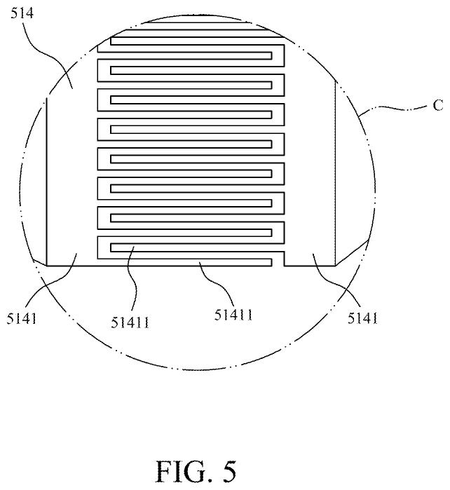

FIG. 4 illustrates a bottom view of the first filter structure 51 of FIG. 1, wherein an insulation layer is omitted for the purpose of the clear explanation. FIG. 5 illustrates an enlarged view of an area “C” shown in FIG. 4. Referring to FIGS. 1, 4 and 5, the first filter structure 51 may be a surface acoustic wave (SAW) filter that may have at least one transducing region 512 and at least one conductive region 513, and may include a piezoelectric material 511, at least one transducing element 514, a first metal layer 516 a plurality of electrical contacts 515, and a cavity 15 (or a recess portion 16).

The piezoelectric material 511 may have a first surface (e.g., a top surface) and a second surface 5112 (e.g., a bottom surface) opposite to the first surface. The transducing region 512 and the conductive region 513 may be disposed adjacent to the second surface 5112 or the first surface of the piezoelectric material 511. The first metal layer 516 (e.g., a copper layer) may be disposed on the second surface 5112 or the first surface of the piezoelectric material 511. The electrical contacts 515 (e.g., pads or bumps) may be disposed adjacent to the second surface 5112 of the piezoelectric material 511. A portion of the first metal layer 516 disposed in the transducing region 512 is the transducing element 514, and the other portion of the first metal layer 516 is disposed in the conductive region 513. An insulation layer may cover and protect the first metal layer 516 in the transducing region 512. A second metal layer (e.g., a copper layer) may be disposed on the portion of the first metal layer 516 that is in the conductive region 513 for electrical connection. The second metal layer may be electrically connected to the electrical contacts 515. Further, the first metal layer 516 may be electrically connected to the electrical contacts 515.

The transducing element 514 may be disposed adjacent to the second surface 5112 or the first surface of the piezoelectric material 511 and within the transducing region 512, and may include at least a pair of inter-digital transducer (IDT) electrodes 5141. Each of the inter-digital transducer (IDT) electrodes 5141 may include a plurality of electrode fingers 51411 parallel with each other. For example, each of the inter-digital transducer (IDT) electrodes 5141 may be in a comb shape. The electrode fingers 51411 of the inter-digital transducer (IDT) electrodes 5141 may be interlocking, and may be in a fashion of a zipper. It is noted that the electrode fingers 51411 of the inter-digital transducer (IDT) electrodes 5141 may not contact each other. In addition, the electrical contacts 515 of the first filter structure 51 may be electrically connected and physically connected to the first redistribution structure 2 through the first protrusion pad 24. A portion of the piezoelectric material 511 may be exposed to the cavity 15 (or a recess portion 16).

Referring to FIGS. 1 and 2, the second filter structure 52 may be a bulk acoustic wave (BAW) filter such as a FBAR (Film Bulk Acoustic Resonator). The second filter structure 52 may include a piezoelectric material 521, a first electrode 522 (e.g., copper electrode), a second electrode 523 (e.g., copper electrode) and a cavity 15 (or a recess portion 16). The first electrode 522 may be disposed adjacent to or disposed on a first surface (e.g., a top surface) of the piezoelectric material 521, and the second electrode 523 may be disposed adjacent to or disposed on a second surface (e.g., a bottom surface) of the piezoelectric material 521. That is, the piezoelectric material 521 may be sandwiched between the first electrode 522 and the second electrode 523. In addition, a size of a portion of the first electrode 522 may be equal to a size of the piezoelectric material 521 from a top view. Another portion of the first electrode 522 may extend along a lateral surface 5211 of the piezoelectric material 521 for electrically connecting and physically connecting to the first redistribution structure 2 through the first protrusion pad 24. Further, a size of the second electrode 523 may be less than the size of the piezoelectric material 521 from a bottom view. A lateral surface 5231 of the second electrode 523 may be recessed from the lateral surface 5211 of the piezoelectric material 521. An end portion of the second electrode 523 may electrically connect and physically connect to the first redistribution structure 2 through the first protrusion pad 24. A portion of the piezoelectric material 521 or the second electrode 523 of the second filter structure 52 may be exposed to the recess portion 16 or the cavity 15. In some embodiments, the piezoelectric material 521 may be electrically connected to the semiconductor substrate 1 through the first electrode 522 and the second electrode 523. A portion of the first electrode 522 may be disposed by a first side (e.g., left side) of the cavity 15, and a portion of the second electrode 523 may be disposed by a second side (e.g., right side) of the cavity 15 opposite to the first side.

In some embodiments, a second acoustic impedance structure 524 may be located over the second filter structure 52. The second acoustic impedance structure 524 may be a cap structure 524 disposed on the first electrode 522. The second acoustic impedance structure 524 (e.g., cap structure 524) and the first electrode 522 may collectively define an empty space 525. Thus, the piezoelectric material 521 may be disposed between the recess portion 16 or the cavity 15 and the empty space 525. The air in the empty space 525 may confine or retain the acoustic energy in the piezoelectric material 521 due to the total reflection. A boundary may be formed between the main body 521 (e.g., the piezoelectric material 521) and the second acoustic impedance structure 524 (e.g., cap structure 524). A second acoustic reflectivity of the acoustic wave at the boundary may be greater than 0.5. In some embodiments, the second acoustic reflectivity may be substantially equal to 1.

Referring to FIGS. 1 and 3, the third filter structure 53 may be a bulk acoustic wave (BAW) filter such as a SMR (Solidly Mounted Resonator). The third filter structure 53 may include a piezoelectric material 531, a first electrode 532 (e.g., copper electrode), a second electrode 533 (e.g., copper electrode) and a cavity 15. The first electrode 532 may be disposed adjacent to or disposed on a first surface (e.g., a top surface) of the piezoelectric material 531, and the second electrode 533 may be disposed adjacent to or disposed on a second surface (e.g., a bottom surface) of the piezoelectric material 531. That is, the piezoelectric material 531 may be sandwiched between the first electrode 532 and the second electrode 533. In addition, a size of a portion of the first electrode 532 may be equal to a size of the piezoelectric material 531 from a top view. Another portion of the first electrode 532 may extend along a lateral surface of the piezoelectric material 531 for electrically connecting and physically connecting to the first redistribution structure 2 through the first protrusion pad 24. Further, a size of the second electrode 533 may be less than the size of the piezoelectric material 531 from a bottom view. A lateral surface of the second electrode 533 may be recessed from the lateral surface of the piezoelectric material 531. An end portion of the second electrode 533 may electrically connect and physically connect to the first redistribution structure 2 through the first protrusion pad 24. A portion of the piezoelectric material 531 or the second electrode 533 of the third filter structure 53 may be exposed to the recess portion 16 or the cavity 15.

In some embodiments, a second acoustic impedance structure 534 may be located over the third filter structure 53. The second acoustic impedance structure 534 may be an acoustic reflector 534 disposed on the first electrode 532. Thus, the piezoelectric material 531 may be disposed between the recess portion 16 or the cavity 15 and the second acoustic impedance structure 534 (e.g., the acoustic reflector 534). The second acoustic impedance structure 534 (e.g., the acoustic reflector 534) may be a multi-layered structure. For example, the second acoustic impedance structure 534 (e.g., the acoustic reflector 534) may include a first layer 5341, a second layer 5342, a third layer 5343, a fourth layer 5344 and a fifth layer 5345 that are stacked on one another. An acoustic impedance of the second layer 5342 may be greater than an acoustic impedance of the first layer 5341. An acoustic impedance of the third layer 5343 may be less than the acoustic impedance of the second layer 534. An acoustic impedance of the fourth layer 5344 may be greater than the acoustic impedance of the third layer 5343. An acoustic impedance of the fifth layer 5345 may be less than the acoustic impedance of the fourth layer 5344. The second acoustic impedance structure 534 (e.g., the acoustic reflector 534) may confine or retain the acoustic energy in the piezoelectric material 531 due to the total reflection.

The first pillars 43 may be disposed around the first filter structure 51, the second filter structure 52 and the third filter structure 53. The first pillar 43 may be disposed on the first via 23. In some embodiments, the first pillar 43 and the first via 23 may be formed concurrently and integrally. The first encapsulant 41 may cover the first redistribution structure 2, and may encapsulate the filter structure 51, 52, 53 and the first pillars 43. The first encapsulant 41 may include a molding compound with or without fillers. The first encapsulant 41 may not extend into the recess portion 16 or the cavity 15. The piezoelectric material 511, 521, 531 of the filter structure 51, 52, 53 may be disposed between the first encapsulant 41 and the first acoustic impedance structure 15 (e.g., the cavity 15).

In some embodiments, a barrier ring or sealing ring may be formed between the first redistribution structure 2 and the first filter structure 51, between the first redistribution structure 2 and the second filter structure 52, and between the first redistribution structure 2 and the third filter structure 53. In some embodiments, a grinding process may be applied to the first encapsulant 41 so as to expose the first pillars 43. Thus, a top surface of the first encapsulant 41 may be coplanar with or aligned with the top surfaces of the first pillars 43.

The third redistribution structure 45 (e.g., a top redistribution structure) may be disposed on the top surface of the first encapsulant 41. In some embodiments, the third redistribution structure 45 may include a third dielectric structure 451 and a third conductive structure. The third dielectric structure 451 may include at least one third dielectric layer. The third conductive structure may include at least one third redistribution layer (RDL) 453 and at least one third via 452. The third redistribution layer (RDL) 453 may be disposed on the third dielectric layer, or may be embedded in the third dielectric structure 451. The third via 452 may extend through the third dielectric layer and may be electrically connected to the third redistribution layer (RDL) 453 and the first pillars 43. The third redistribution layer (RDL) 453 may include a plurality of third pads exposed from a top surface of the third dielectric structure 45. In some embodiments, an L/S (line space and line width) of the third redistribution layer (RDL) 453 of the third redistribution structure 45 may be greater than an L/S of the first redistribution layer (RDL) of the first redistribution structure 2. The third redistribution structure 45 may be electrically connected to the first redistribution structure 2 through the first pillars 43. In addition, the first solders 454 may be disposed on the third pads of the third redistribution layer (RDL) 453 for external connection.

The first amplifier 54 may include a plurality of bumps 57. The bump 57 of the first amplifier 54 may be electrically connected and physically connected to the second protrusion pad 34 of the second redistribution structure 3 through a solder 58. The first amplifier 54 may be vertically aligned with the first filter structure 51. Further, the second amplifier 55 may include a plurality of bumps 57. The bump 57 of the second amplifier 55 may be electrically connected and physically connected to the second protrusion pad 34 of the second redistribution structure 3 through the solder 58. The second amplifier 55 may be vertically aligned with the second filter structure 52. In addition, the third amplifier 56 may include a plurality of bumps 57. The bump 57 of the third amplifier 56 may be electrically connected and physically connected to the second protrusion pad 34 of the second redistribution structure 3 through the solder 58. The third amplifier 56 may be vertically aligned with the third filter structure 53. In some embodiments, the first amplifier 54, the second amplifier 55 and the third amplifier 56 may be same amplifiers or different amplifiers.

The second pillars 44 may be disposed around the first amplifier 54, the second amplifier 55 and the third amplifier 56. The second pillar 44 may be disposed on the second via 33. In some embodiments, the second pillar 44 and the second via 43 may be formed concurrently and integrally. The second encapsulant 42 may cover the second redistribution structure 3, and may encapsulate the first amplifier 54, the second amplifier 55, the third amplifier 56 and the second pillars 44. The second encapsulant 42 may include a molding compound with or without fillers. The second encapsulant 42 may further encapsulate the joint structure formed by the bumps 57 of the amplifiers 54, 55, 56, the solders 58 and the second protrusion pads 34 of the second redistribution structure 3. In some embodiments, a grinding process may be applied to the second encapsulant 42 so as to expose the second pillars 44. Thus, a bottom surface of the second encapsulant 42 may be coplanar with or aligned with the bottom surfaces of the second pillars 44.

The fourth redistribution structure 46 (e.g., a bottom redistribution structure) may be disposed on the bottom surface of the second encapsulant 42. In some embodiments, the fourth redistribution structure 46 may include a fourth dielectric structure 461 and a fourth conductive structure. The fourth dielectric structure 461 may include at least one fourth dielectric layer. The fourth conductive structure may include at least one fourth redistribution layer (RDL) 463 and at least one fourth via 462. The fourth redistribution layer (RDL) 463 may be disposed on the fourth dielectric layer, or may be embedded in the fourth dielectric structure 461. The fourth via 462 may extend through the fourth dielectric layer and may be electrically connected to the fourth redistribution layer (RDL) 463 and the second pillars 44. The fourth redistribution layer (RDL) 463 may include a plurality of fourth pads exposed from a bottom surface of the fourth dielectric structure 46. In some embodiments, an L/S (line space and line width) of the fourth redistribution layer (RDL) 463 of the fourth redistribution structure 46 may be greater than an L/S of the second redistribution layer (RDL) of the second redistribution structure 3. The fourth redistribution structure 46 may be electrically connected to the second redistribution structure 3 through the second pillars 44. In addition, the second solders 464 may be disposed on the fourth pads of the fourth redistribution layer (RDL) 463 for external connection.

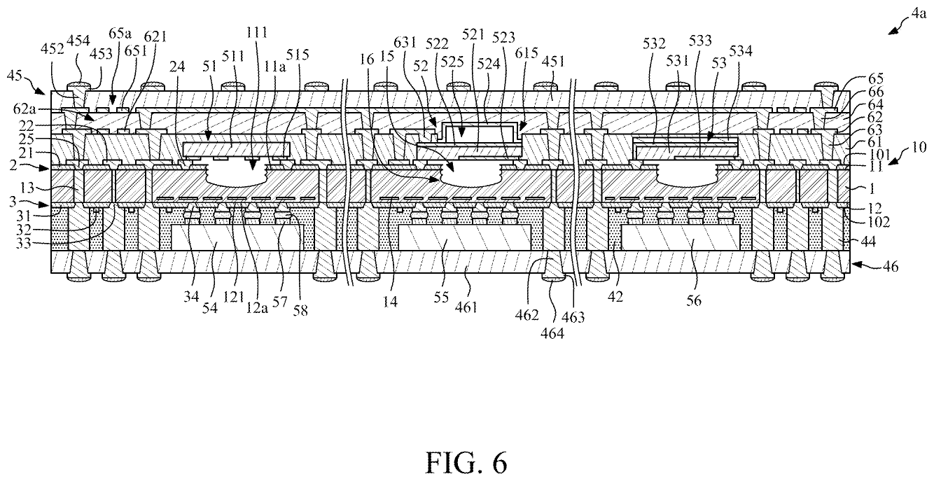

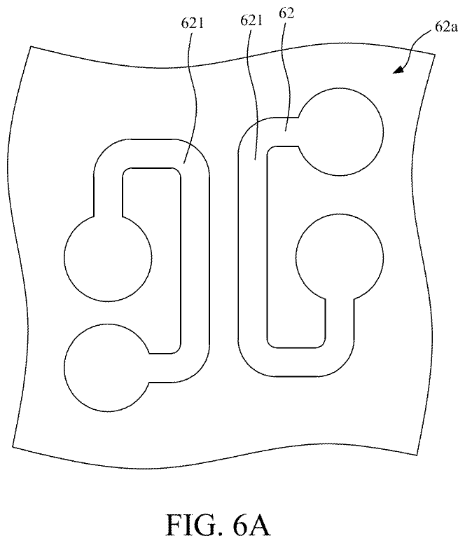

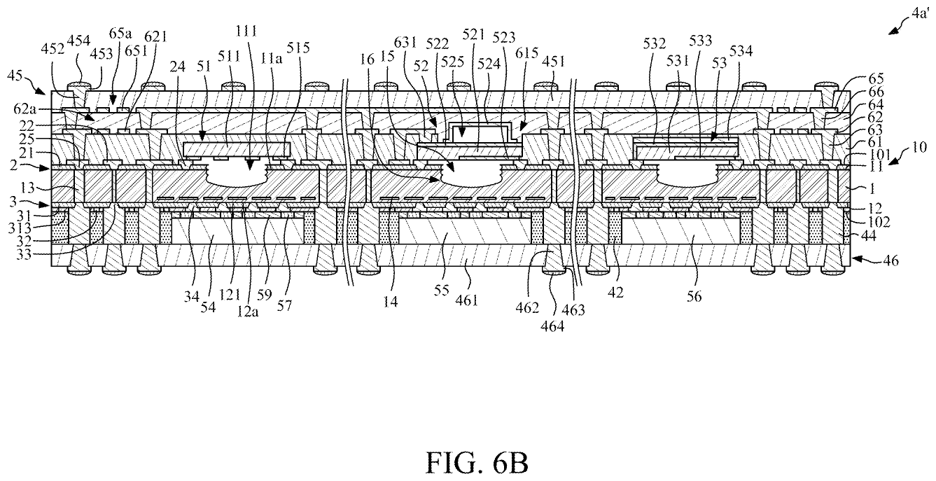

FIG. 6 illustrates a cross-sectional view of a package structure 4a according to some embodiments of the present disclosure. FIG. 6A illustrates a top view of an inductor 621 of FIG. 6. The package structure 4a of FIG. 6 may be similar to the package structure 4 of FIG. 1 except that the first encapsulant 41 and the first pillars 43 of FIG. 1 are replaced by a fifth dielectric layer 61, a fifth conductive structure 62, a sixth dielectric layer 64 and a sixth conductive structure 65. In addition, the first conductive structure 22 of the first redistribution structure 2 may further include at least one periphery protrusion pad 25 disposed around the first protrusion pad 24.

The fifth dielectric layer 61 may cover the first redistribution structure 2, the first filter structure 51, the second filter structure 52 and the third filter structure 53. The fifth dielectric layer 61 may not extend into the recess portion 16 or the cavity 15. In some embodiments, a barrier ring or sealing ring may be formed between the first redistribution structure 2 and the first filter structure 51, between the first redistribution structure 2 and the second filter structure 52, and between the first redistribution structure 2 and the third filter structure 53. In some embodiments, the fifth dielectric layer 61 may define an accommodating hole 615 to expose a portion of the top surface of the first electrode 522. A lower portion of the second acoustic impedance structure 524 (e.g., cap structure 524) may be disposed in the accommodating hole 615 to contact or connect to the first electrode 522. An upper portion of the second acoustic impedance structure 524 (e.g., cap structure 524) may protrude from a top surface of the fifth dielectric layer 61.

The fifth conductive structure 62 may be disposed on the top surface of the fifth dielectric layer 61. In some embodiments, the fifth conductive structure 62 may include a fifth redistribution layer (RDL) and at least one fifth via 63. The fifth redistribution layer (RDL) may be disposed on the fifth dielectric layer 61. The fifth via 63 may extend through the fifth dielectric layer 61 and may be electrically connected to the fifth redistribution layer (RDL) of the fifth conductive structure 62 and the periphery protrusion pad 25 of the first redistribution structure 2. In some embodiments, the fifth via 63 may include a shorter via 631 disposed over the piezoelectric material 521 of the second filter structure 52. The shorter via 631 may extend through a portion of the fifth dielectric layer 61 that is disposed on the first electrode 522 so as to electrically connect to the first electrode 522. In some embodiments, as shown in FIG. 6A, the fifth conductive structure 62 may include at least one integrated passive device (IPD) such as an inductor 621 disposed in a first IPD region 62a.

The sixth dielectric layer 64 may cover the fifth dielectric layer 61 and the fifth conductive structure 62. The sixth dielectric layer 64 may further cover the upper portion of the second acoustic impedance structure 524 (e.g., cap structure 524) and may extend into the accommodating hole 615 of the fifth dielectric layer 61. The sixth conductive structure 65 may be disposed on the top surface of the sixth dielectric layer 64. In some embodiments, the sixth conductive structure 65 may include a sixth redistribution layer (RDL) and at least one sixth via 66. The sixth redistribution layer (RDL) may be disposed on the sixth dielectric layer 64. The sixth via 66 may extend through the sixth dielectric layer 64 and may be electrically connected to the sixth redistribution layer (RDL) of the sixth conductive structure 65 and the fifth redistribution layer (RDL) of the fifth conductive structure 62. In some embodiments, the sixth conductive structure 65 may include at least one integrated passive device (IPD) such as an inductor 651 disposed in a second IPD region 65a. The second IPD region 65a may be aligned with the first IPD region 62a. The pattern of the inductor 651 may be same as or different from the pattern of the inductor 621. The inductor 651 may be aligned with the inductor 621. The integrated passive device (IPD) (e.g., the inductor 621) of the fifth conductive structure 62 and the integrated passive device (IPD) (e.g., the inductor 651) of the sixth conductive structure 65 can achieve the effect of matching and tuning.

The third redistribution structure 45 may be disposed on the top surface of the sixth dielectric layer 64. In some embodiments, the third dielectric structure 451 of the third redistribution structure 45 may cover the sixth dielectric layer 64 and the sixth conductive structure 65. The third via 452 of the third redistribution structure 45 may extend through the third dielectric layer and may be electrically connected to the third redistribution layer (RDL) 453 of the third redistribution structure 45 and the sixth redistribution layer (RDL) of the sixth conductive structure 65.

FIG. 6B illustrates a cross-sectional view of a package structure 4a′ according to some embodiments of the present disclosure. The package structure 4a′ of FIG. 6B may be similar to the package structure 4a of FIG. 6 except for the bonding between the amplifiers (e.g., the first amplifier 54, the second amplifier 55 and the third amplifier 56) and the second redistribution structure 3 of the semiconductor substrate structure 10. As shown in FIG. 6B, the second redistribution structure 3 of the semiconductor substrate structure 10 may further include a bottommost dielectric layer 313 surrounding the second protrusion pads 34. The bottom surface of the bottommost dielectric layer 313 may be aligned with or coplanar with the bottom surface of the second protrusion pad 34. Thus, the second protrusion pads 34 may be also referred to as “a second pad”. In addition, the amplifier 54, 55, 56 may further include a topmost dielectric layer 59 surrounding the bumps 57. The top surface of the topmost dielectric layer 59 may be aligned with or coplanar with the top surface of the bump 57. In some embodiments, the topmost dielectric layer 59 of the amplifier 54, 55, 56 may contact the bottommost dielectric layer 313 of the second redistribution structure 3 of the semiconductor substrate structure 10 directly. The bumps 57 of the amplifier 54, 55, 56 may contact the second protrusion pads 34 of the second redistribution structure 3 of the semiconductor substrate structure 10 directly. In some embodiments, the bumps 57 of the amplifier 54, 55, 56 may be misaligned with the second protrusion pads 34 of the second redistribution structure 3 of the semiconductor substrate structure 10.

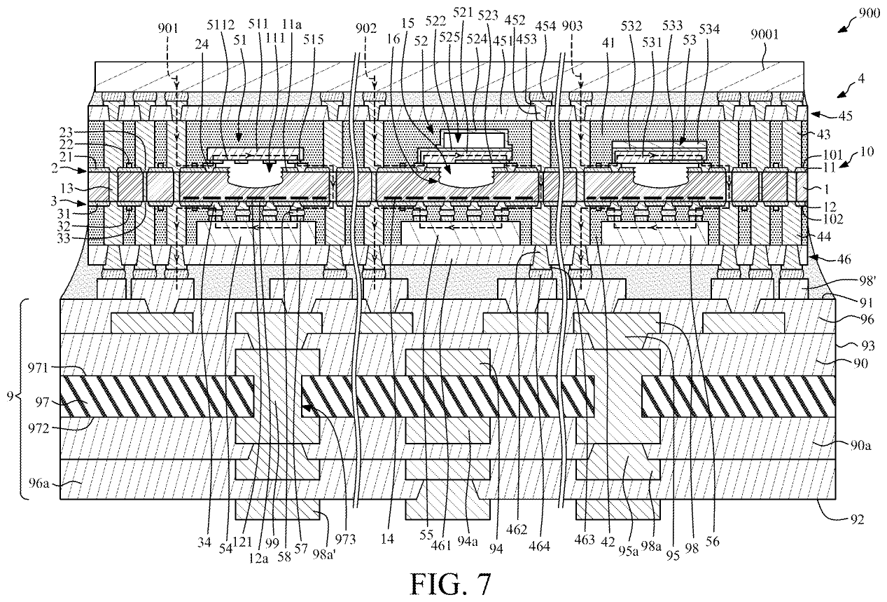

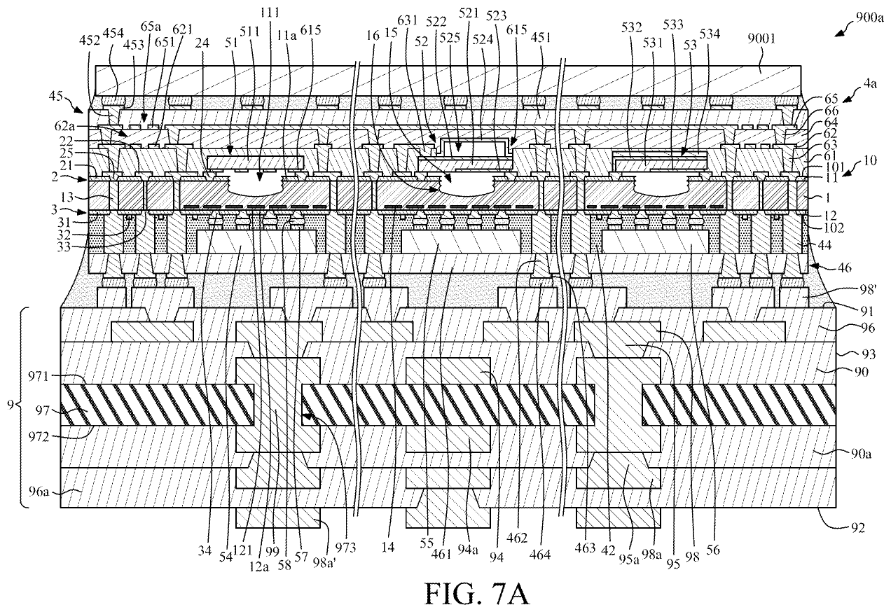

FIG. 7 illustrates a cross-sectional view of an assembly structure 900 according to some embodiments of the present disclosure. The assembly structure 900 may include a substrate 9, a package structure 4 and an antenna module 9001. The antenna module 9001 may be disposed over the package structure 4, and electrically connected to the package structure 4. The package structure 4 may be disposed over the substrate 9, and electrically connected to the substrate 9. The package structure 4 of FIG. 7 may be same as or similar to the package structure 4 of FIG. 1.

The substrate 9 may include at least one dielectric layer (including, for example, one first upper dielectric layer 90, one second upper dielectric layer 96, one first lower dielectric layer 90a and one second lower dielectric layer 96a), at least one circuit layer (including, for example, one first upper circuit layer 94, two second upper circuit layers 98, 98′, one first lower circuit layer 94a and two second lower circuit layers 98a, 98a′ formed of a metal, a metal alloy, or other conductive material) in contact with the dielectric layer(s) 90, 96, 90a, 96a, and at least one inner conductive via (including, for example, a plurality of upper interconnection vias 95 and a plurality of lower interconnection vias 95a). In some embodiments, the substrate 9 may be similar to a core substrate that further includes a core portion 97. The circuit layers 94, 98, 98′, 94a, 98a, 98a′ of the substrate 9 may be also referred to as “a low-density circuit layer”. As shown in FIG. 7, the substrate 9 may have a top surface 91, a bottom surface 92 opposite to the top surface 91, and a lateral surface 93 extending between the top surface 91 and the bottom surface 92. As shown in FIG. 7, the lateral surface of the package structure 4 may be displaced or recessed from the lateral surface 93 of the substrate 9.

The core portion 97 may have a top surface 971 and a bottom surface 972 opposite to the top surface 971, and may define a plurality of through holes 973 extending through the core portion 97. An interconnection via 99 may be disposed or formed in each through hole 973 for vertical connection. The first upper dielectric layer 90 may be disposed on the top surface 971 of the core portion 97. The second upper dielectric layer 96 may be stacked or disposed on the first upper dielectric layer 90. In addition, the first lower dielectric layer 90a may be disposed on the bottom surface 972 of the core portion 97. The second lower dielectric layer 96a may be stacked or disposed on the first lower dielectric layer 90a.

An L/S of the circuit layers 94, 98, 98′, 94a 98a, 98a′ may be greater than an L/S of the redistribution structures 2, 3, 45, 46. In some embodiments, the first upper circuit layer 94 may be formed or disposed on the top surface 971 of the core portion 97, and covered by the first upper dielectric layer 90. The second upper circuit layer 38 may be formed or disposed on the first upper dielectric layer 90, and covered by the second upper dielectric layer 96. In some embodiments, the second upper circuit layer 98 is electrically connected to the first upper circuit layer 94 through the upper interconnection vias 95. Each upper interconnection via 95 tapers downwardly. In addition, the second upper circuit layer 98′ may be disposed on and protrudes from the top surface of the second upper dielectric layer 96. In some embodiments, the second upper circuit layer 98 may be electrically connected to the second upper circuit layer 98′ through the upper interconnection vias 95.

In some embodiments, the first lower circuit layer 94a may be formed or disposed on the bottom surface 972 of the core portion 97, and covered by the first lower dielectric layer 90a. The second lower circuit layer 98a may be formed or disposed on the first lower dielectric layer 90a, and covered by the second lower dielectric layer 96a. In some embodiments, the second lower circuit layer 98a may be electrically connected to the first lower circuit layer 94a through the lower interconnection vias 95a. The lower interconnection via 95a tapers upwardly. In addition, the second lower circuit layer 98a′ may be disposed on and protrudes from the bottom surface of the second lower dielectric layer 96a. In some embodiments, the second lower circuit layer 98a′ may be electrically connected to the second lower circuit layer 98a through the lower interconnection vias 95a. In some embodiments, each interconnection via 99 electrically connects the first upper circuit layer 94 and the first lower circuit layer 94a.

As shown in FIG. 7, electromagnetic waves may be converted into electrical signals by the antenna module 9001. The electrical signals from the antenna module 9001 may be transmitted to the substrate 9 through three paths 901, 902, 903. In the first path 901, the electrical signals may be transmitted to the first filter structure 51 through the third redistribution structure 45, the first pillar 43 and the first redistribution structure 2. The electrical signals may be filtered by the first filter structure 51, and only desired electrical signals remain. The cavity 15 may facilitate the signal integrity. After being processed by the first filter structure 51, the remaining electrical signals or desired electrical signals may be transmitted to the first amplifier 54 through the first redistribution structure 2, the through via 13 and the second redistribution structure 3. After being amplified by the first amplifier 54, the signals may be transmitted to the semiconductor substrate 1. After being processed by the semiconductor substrate 1, the signals may be transmitted to the substrate 9 through the second redistribution structure 3, the second pillar 44 and the fourth redistribution structure 46. Further, in the second path 902, the electrical signals may be transmitted to the second filter structure 52 through the third redistribution structure 45, the first pillar 43 and the first redistribution structure 2. The electrical signals may be filtered by the second filter structure 52, and only desired electrical signals remain. The cavity 15 may facilitate the signal integrity. After being processed by the second filter structure 52, the electrical signals may be transmitted to the second amplifier 55 through the first redistribution structure 2, the through via 13 and the second redistribution structure 3. After being amplified by the second amplifier 55, the signal may be transmitted to the semiconductor substrate 1. After being processed by the semiconductor substrate 1, the signals may be transmitted to the substrate 9 through the second redistribution structure 3, the second pillar 44 and the fourth redistribution structure 46. In addition, in the third path 903, the electrical signals may be transmitted to the third filter structure 53 through the third redistribution structure 45, the first pillar 43 and the first redistribution structure 2. The electrical signals may be filtered by the third filter structure 53, and only desired electrical signals remain. The cavity 15 may facilitate the signal integrity. After being processed by the third filter structure 53, the electrical signals may be transmitted to the third amplifier 56 through the first redistribution structure 2, the through via 13 and the second redistribution structure 3. After being amplified by the third amplifier 56, the signal may be transmitted to the semiconductor substrate 1. After being processed by the semiconductor substrate 1, the signals may be transmitted to the substrate 9 through the second redistribution structure 3, the second pillar 44 and the fourth redistribution structure 46. Therefore, the transmitting path of the signals from the antenna module 9001 to the substrate 9 may be shortened. The total size of the package structure 4 may be reduced to a minimum size.

FIG. 7A illustrates a cross-sectional view of an assembly structure 900a according to some embodiments of the present disclosure. The assembly structure 900a of FIG. 7A may be similar to the assembly structure 900 of FIG. 7, except that the package structure 4 of FIG. 7 may be replaced by the package structure 4a of FIG. 6.

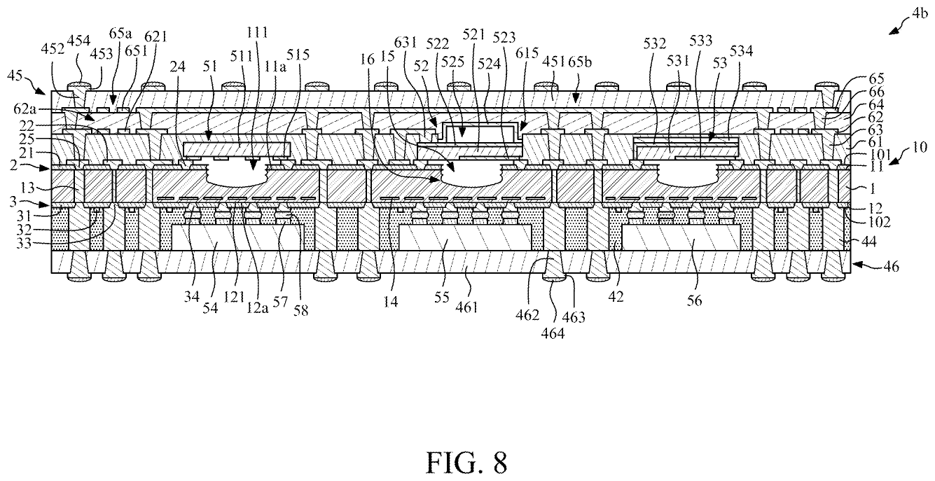

FIG. 8 illustrates a cross-sectional view of a package structure 4b according to some embodiments of the present disclosure. The package structure 4b of FIG. 8 may be similar to the package structure 4a of FIG. 6. The package structure 4b may include a shielding structure 65b formed by the fifth vias 63 disposed around the filter structure 51, 52, 53, the sixth vias 66 connected to the fifth vias 63 and a portion of the sixth redistribution layer (RDL) of the sixth conductive structure 65 connected to the sixth vias 66. The shielding structure 65b may protect the elements disposed therein from noise interference. The integrated passive device (IPD) (e.g., the inductor 621) of the fifth conductive structure 62 and the integrated passive device (IPD) (e.g., the inductor 651) of the sixth conductive structure 65 may be disposed outside the shielding structure 65b.

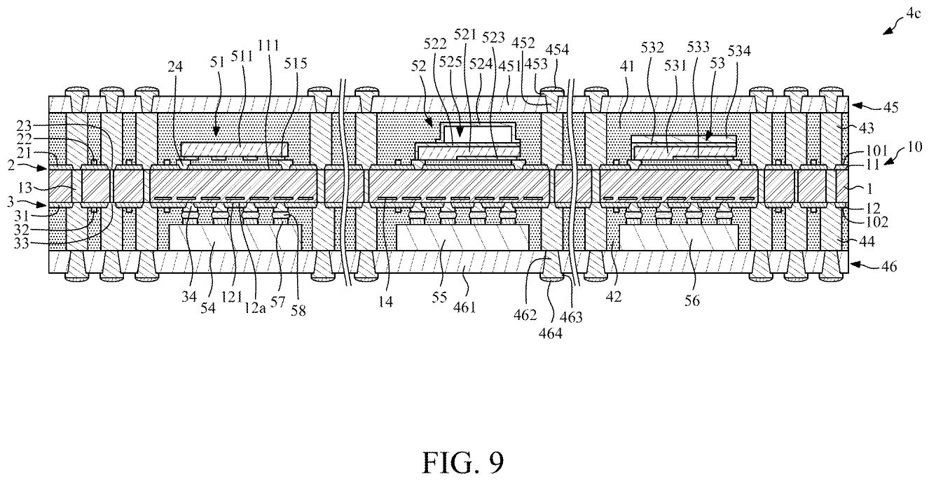

FIG. 9 illustrates a cross-sectional view of a package structure 4c according to some embodiments of the present disclosure. The package structure 4c of FIG. 9 may be similar to the package structure 4 of FIG. 1 except that the recess portion 16 (the groove 16) or the cavity 15 may be omitted. The entire first surface 11 of the semiconductor substrate 1 may be a flat surface.

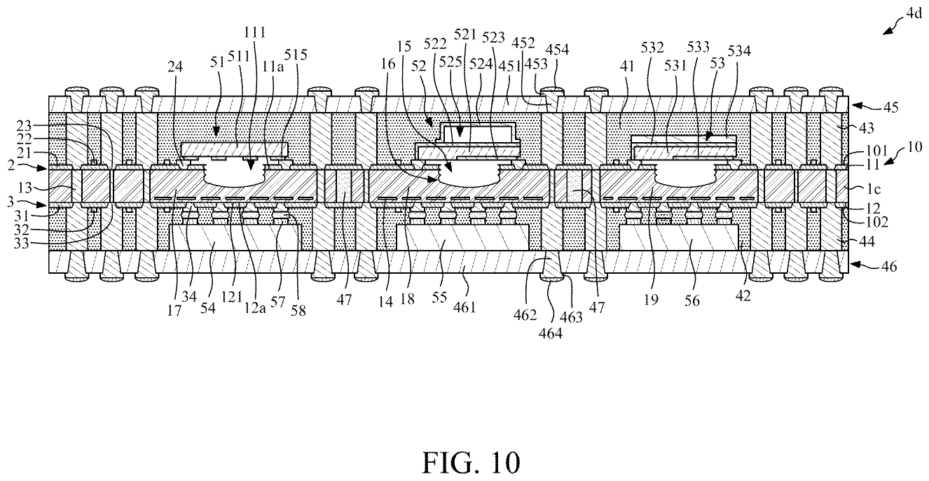

FIG. 10 illustrates a cross-sectional view of a package structure 4d according to some embodiments of the present disclosure. The package structure 4d of FIG. 10 may be similar to the package structure 4 of FIG. 1 except that the semiconductor substrate 1c may be a reconstruction structure. For example, the semiconductor substrate 1c may include a plurality of separated RF dice 17, 18, 19 and an intermediate material 47 therebetween. There may be a gap between the lateral surfaces of the RF dice 17, 18, 19. The intermediate material 47 may be disposed in such gap. The intermediate material 47 may be a molding compound or a dielectric layer. The first dielectric structure 21 of the first redistribution structure 2 and the second dielectric structure 31 of the second redistribution structure 3 may cover the intermediate material 47.

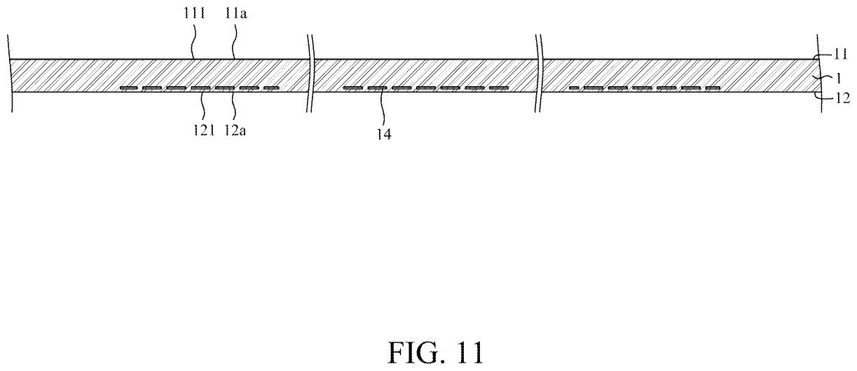

FIG. 11 through FIG. 24 illustrate an example of a method for manufacturing a package structure according to some embodiments of the present disclosure. In some embodiments, the method is for manufacturing a package structure such as the package structure 4 shown in FIG. 1.

Referring to FIG. 11, a semiconductor substrate 1 may be provided. The semiconductor substrate 1 may have a first surface 11 and a second surface 12 opposite to the first surface 11. The semiconductor substrate 1 may include an active circuit layer 14 disposed adjacent to the second surface 12. Thus, the second surface 12 may be an active surface. In some embodiments, the first surface 11 of the semiconductor substrate 1 may include a first portion 11a. The first portion 11a may define a filtering region 111 configured to filter a signal. The second surface 12 of the semiconductor substrate 1 may include a second portion 12a. The second portion 12a may define an amplifying region 121 configured to amplify a signal.

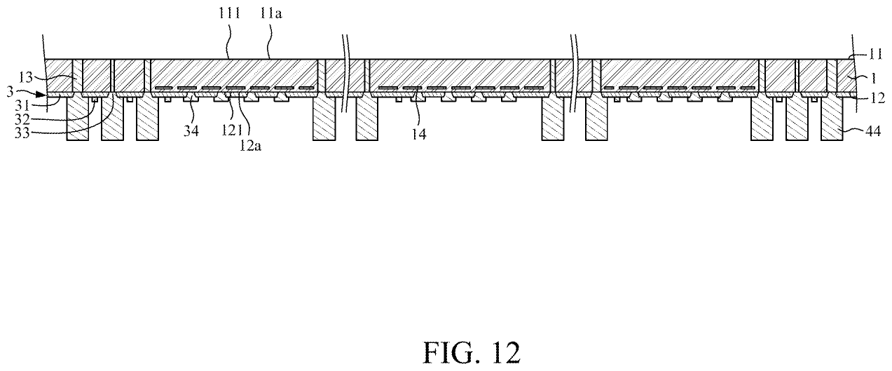

Referring to FIG. 12, a plurality of through vias 13 may be formed to extend through the semiconductor substrate 1, and a second redistribution structure 3 and a plurality of second pillars 44 may be formed or disposed on the second surface 12 of the semiconductor substrate 1. In some embodiments, the second redistribution structure 3 may include a second dielectric structure 31 and a second conductive structure 32. The second dielectric structure 31 may include at least one first dielectric layer. The second conductive structure 32 may include at least one second redistribution layer (RDL), at least one second via 33 and at least one second protrusion pad 34. The second redistribution layer (RDL) may be disposed on the second dielectric layer, or may be embedded in the second dielectric structure 31. The second via 33 may extend through the second dielectric layer. The second protrusion pad 34 may extend through the second dielectric layer, and may be exposed from a bottom surface of the second dielectric structure 31. The second pillar(s) 44 may be formed or disposed on the second via(s) 33. In some embodiments, the second pillar(s) 44 and the second via(s) 33 may be formed concurrently and integrally. In some embodiments, the second protrusion pad(s) 34 may be located at the amplifying region 121 of the second surface 12 of the semiconductor substrate 1. The second pillar(s) 44 may be located around the second protrusion pad(s) 34. Thus, the second pillar(s) 44 may be located outside the amplifying region 121.

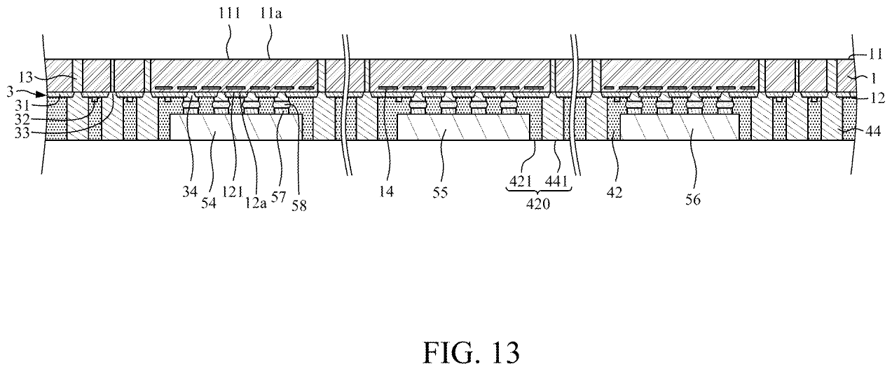

Referring to FIG. 13, a plurality of amplifiers (e.g., a first amplifier 54, a second amplifier 55 and a third amplifier 56) may be electrically connected to and physically connected to the second protrusion pads 34 through a plurality of bumps 57 and a plurality of solders 58. Thus, the amplifiers 54, 55, 56 may be disposed over and/or electrically connected to the amplifying region 121 of the second surface 12 of the semiconductor substrate 1. The amplifiers 54, 55, 56 of FIG. 13 may be same as or similar to the amplifiers 54, 55, 56 of FIG. 1. The amplifiers 54, 55, 56 may include a low noise amplifier (LNA) and/or a power amplifier (PA). In some embodiments, the amplifiers 54, 55, 56 may be attached to and/or electrically connected to the second redistribution structure 3.

Then, a second encapsulant 42 may be formed or disposed to cover the second redistribution structure 3, and to encapsulate the amplifiers 54, 55, 56 and the second pillars 44. The second encapsulant 42 may further encapsulate the joint structure formed by the bumps 57 of the amplifiers 54, 55, 56, the solders 58 and the second protrusion pads 34 of the second redistribution structure 3. In some embodiments, a grinding process may be applied to the second encapsulant 42 so as to expose the second pillars 44. Thus, a bottom surface 421 of the second encapsulant 42 may be coplanar with or aligned with the bottom surfaces 441 of the second pillars 44 so as to form a bottom surface 420 of the second encapsulant 42.

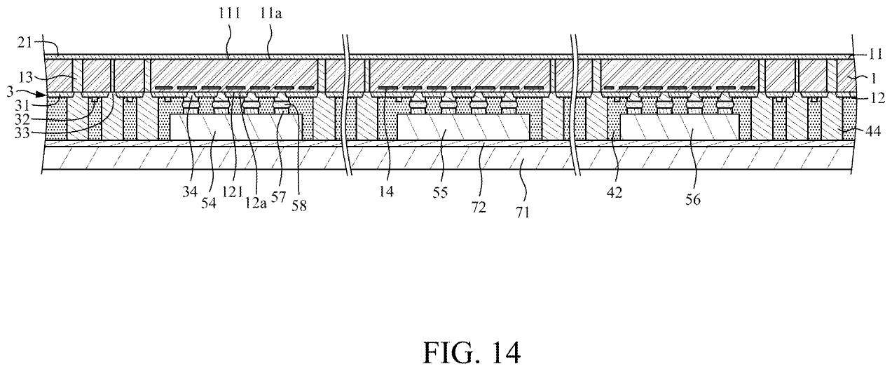

Referring to FIG. 14, the structure of FIG. 13 may be placed or disposed on a release layer 72 on a carrier 71. Then, a first dielectric structure 21 may be formed or disposed on the first surface 11 of the semiconductor substrate 1. The first dielectric structure 21 may include at least one first dielectric layer.

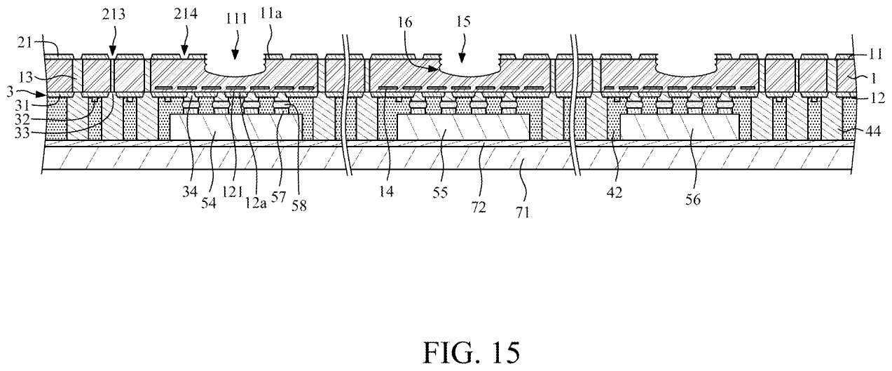

Referring to FIG. 15, at least one first opening 213, at least one second opening 214 and at least one recess portion 16 (or groove 16) may be formed in the first dielectric structure 21. The first opening 213 may extend through the first dielectric layer of the first dielectric structure 21 to expose the through vias 13 of the semiconductor substrate 1. The first opening 213 may be located outside the filtering region 111 of the first surface 11 of the semiconductor substrate 1. The second opening 214 may extend through the first dielectric layer of the first dielectric structure 21 to expose a portion of the semiconductor substrate 1. The second opening 214 may be located in the filtering region 111 of the first surface 11 of the semiconductor substrate 1. The recess portion 16 may be located at the first portion 11a, may extend through the first dielectric layer of the first dielectric structure 21, and may further extend into the semiconductor substrate 1 so as to define a cavity 15. The cavity 15 defined by the recess portion 16 or the groove 16 is located in the first portion 11a of the first surface 11 of the semiconductor substrate 1. Thus, the cavity 15 may be located adjacent to the filtering region 111. The cavity 15 may be communicated with the filtering region 111 of the first surface 11.

A bottom end of the cavity 15 (e.g., the bottom wall of the recess portion 16) may be closer to the active circuit layer 14 than the first surface 11 of the semiconductor substrate 1 is. Thus, the active circuit layer 14 may be located between the recess portion 16 or the cavity 15 and the second surface 12 of the semiconductor substrate 1.

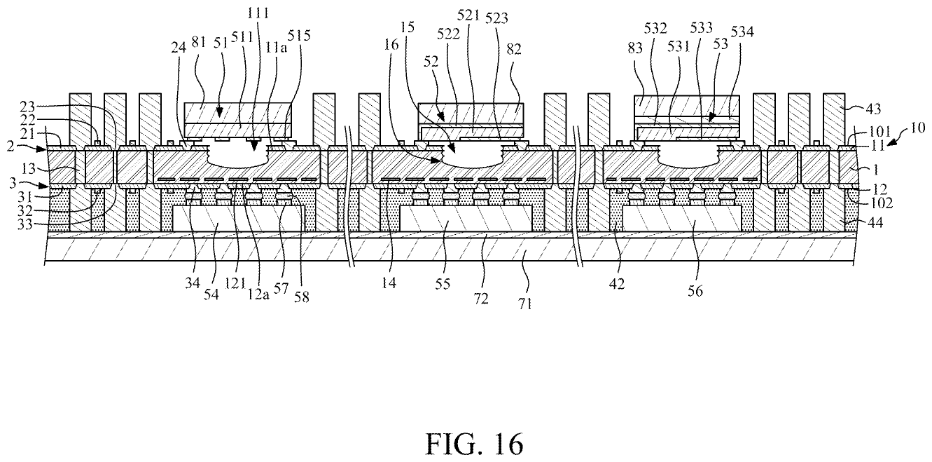

Referring to FIG. 16, a first conductive structure 22 may be formed on or disposed on or disposed in the first dielectric layer. The first conductive structure 22 may include at least one first redistribution layer (RDL), at least one first via 23 and at least one first protrusion pad 24. The first redistribution layer (RDL) may be disposed on the first dielectric layer, or may be embedded in the first dielectric structure 21. The first via 23 may be disposed in the first opening 213 so as to extend through the first dielectric layer. The first protrusion pad 24 may be disposed in the second opening 214 so as to extend through the first dielectric layer, and may be exposed from a top surface of the first dielectric structure 21. Meanwhile, the first dielectric structure 21 and the first conductive structure 22 may collectively form a first redistribution structure 2 disposed on the first surface 11 of the semiconductor substrate 1. Further, the semiconductor substrate 1, the first redistribution structure 2 and the second redistribution structure 3 may collectively form a semiconductor substrate structure 10. In addition, a plurality of first pillars 43 may be formed or disposed on the first via 23. In some embodiments, the first pillar 43 and the first via 23 may be formed concurrently and integrally.

Then, a piezoelectric material 511 attached to a first carrier 81 may be provided. The assembly of the piezoelectric material 511 and the first carrier 81 may be formed through a singulation process. Then, the assembly of the piezoelectric material 511 and the first carrier 81 may be attached to or connected to the first protrusion pad 24. Thus, the piezoelectric material 511 may be attached to and/or electrically connected to the first redistribution structure 2 of the semiconductor substrate structure 10. A material of the first carrier 81 may include silicon. The piezoelectric material 511 of FIG. 16 may be same as or similar to the piezoelectric material 511 of FIG. 1. The piezoelectric material 511 may be disposed over the first amplifier 54, and a recess portion 16 or a cavity 15 may be disposed therebetween. The piezoelectric material 511 and the cavity 15 (or the recess portion 16) may collectively form a first filter structure 51.

Then, a piezoelectric material 521 attached to a second carrier 82 may be provided. The assembly of the piezoelectric material 521 and the second carrier 82 may be formed through a singulation process. Then, the assembly of the piezoelectric material 521 and the second carrier 82 may be attached to or connected to the first protrusion pad 24. Thus, the piezoelectric material 521 may be attached to and/or electrically connected to the first redistribution structure 2 of the semiconductor substrate structure 10. A material of the second carrier 82 may include silicon. The piezoelectric material 521 of FIG. 16 may be same as or similar to the piezoelectric material 521 of FIG. 1. The piezoelectric material 521 may be disposed over the second amplifier 55, and a recess portion 16 or a cavity 15 may be disposed therebetween. The piezoelectric material 521 and the cavity 15 (or the recess portion 16) may collectively form a second filter structure 52.

Then, a piezoelectric material 531 and a second acoustic impedance structure 534 (e.g., the acoustic reflector 534) attached to a third carrier 83 may be provided. The assembly of the piezoelectric material 531, the second acoustic impedance structure 534 (e.g., the acoustic reflector 534) and the third carrier 83 may be formed through a singulation process. Then, the assembly of the piezoelectric material 531, the second acoustic impedance structure 534 (e.g., the acoustic reflector 534) and the third carrier 83 may be attached to or connected to the first protrusion pad 24. Thus, the piezoelectric material 531 may be attached to and/or electrically connected to the first redistribution structure 2 of the semiconductor substrate structure 10. A material of the third carrier 83 may include silicon. The piezoelectric material 531 and the second acoustic impedance structure 534 (e.g., the acoustic reflector 534) of FIG. 16 may be same as or similar to the piezoelectric material 531 and the second acoustic impedance structure 534 (e.g., the acoustic reflector 534) of FIG. 1. The piezoelectric material 531 may be disposed over the third amplifier 53, and a recess portion 16 or a cavity 15 may be disposed therebetween. The piezoelectric material 531, the second acoustic impedance structure 534 (e.g., the acoustic reflector 534) and the cavity 15 (or the recess portion 16) may collectively form a third filter structure 53.

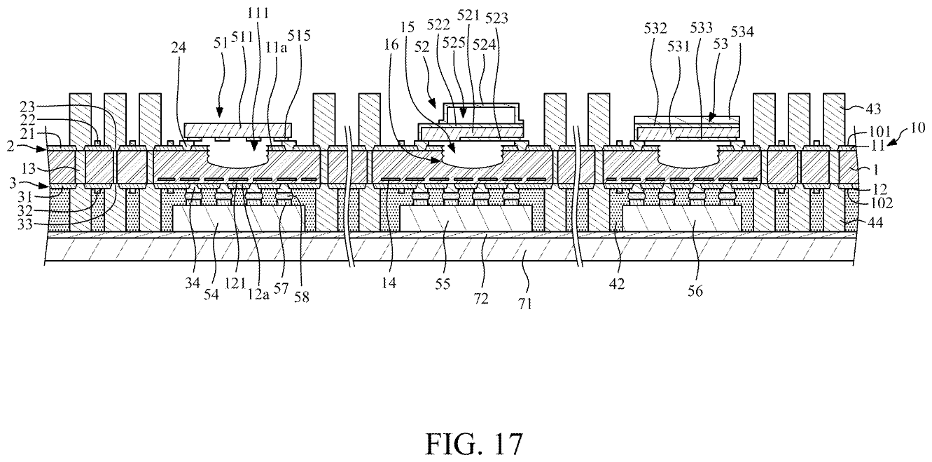

Referring to FIG. 17, the first carrier 81, the second carrier 82 and the third carrier 83 may be removed or lifted off by, for example, a hydrogen ion implantation separation method so as to reduce the manufacturing cost. Then, a second acoustic impedance structure 524 (e.g., cap structure 524) may be formed or disposed on the first electrode 522 of the second filter structure 52. The second acoustic impedance structure 524 (e.g., cap structure 524) and the first electrode 522 may collectively define an empty space 525.

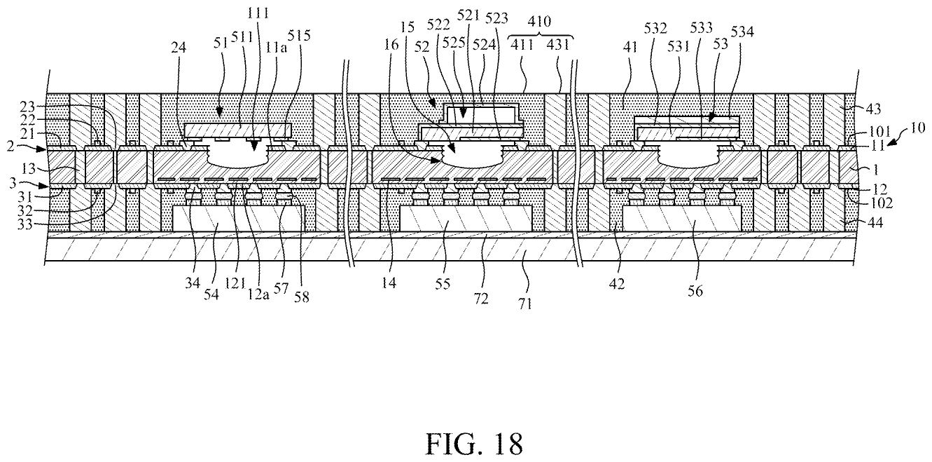

Referring to FIG. 18, a first encapsulant 41 may be formed or disposed to cover the first redistribution structure 2, and to encapsulate the first filter structure 51, the second filter structure 52, the third filter structure 53 and the first pillars 43. The first encapsulant 41 may include a molding compound with or without fillers. The first encapsulant 41 may not extend into the recess portion 16 or the cavity 15. In some embodiments, a barrier ring or sealing ring may be formed between the first redistribution structure 2 and the piezoelectric material 511 of the first filter structure 51, between the first redistribution structure 2 and the piezoelectric material 521 of the second filter structure 52, and between the first redistribution structure 2 and the piezoelectric material 531 of the third filter structure 53. In some embodiments, a grinding process may be applied to the first encapsulant 41 so as to expose the first pillars 43. Thus, a top surface of 411 the first encapsulant 41 may be coplanar with or aligned with the top surfaces 431 of the first pillars 43 so as to form a top surface 410 of the first encapsulant 41.

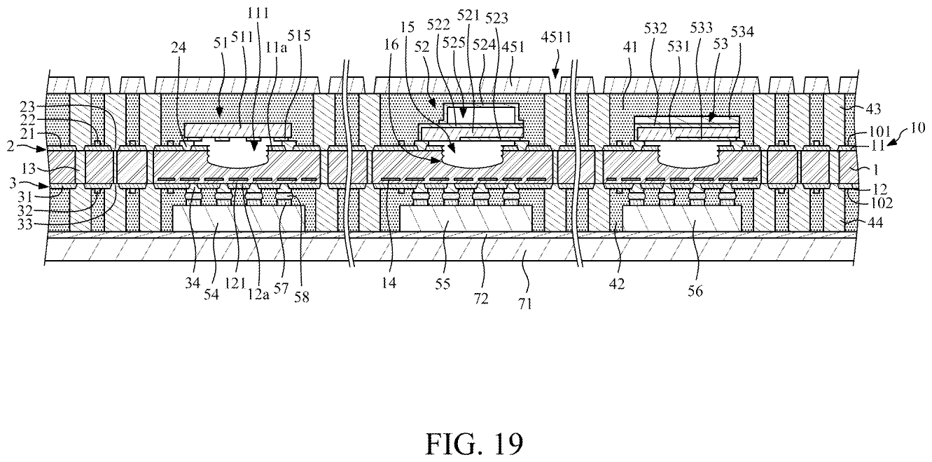

Referring to FIG. 19, a third dielectric structure 451 may be formed or disposed on the top surface 410 of the first encapsulant 41. The third dielectric structure 451 may include at least one third dielectric layer. Then, a plurality of openings 4511 may be formed in the third dielectric structure 451 to expose the first pillars 43.

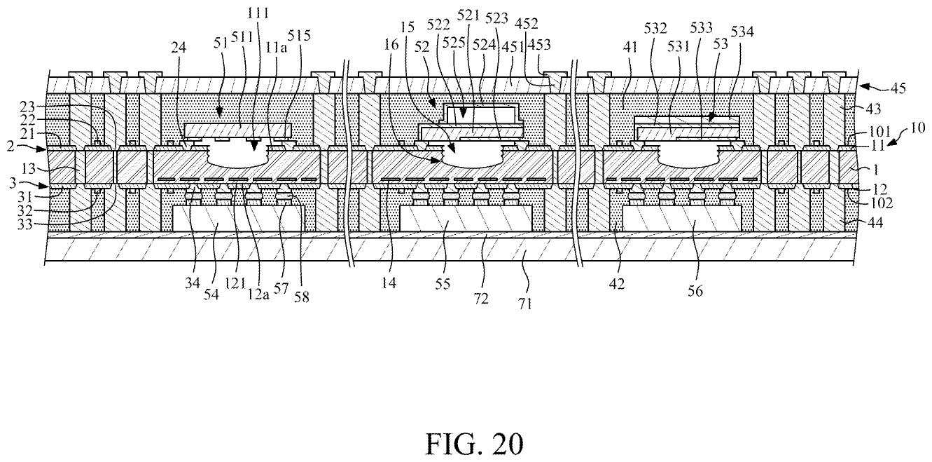

Referring to FIG. 20, a third conductive structure may be formed on or formed in the third dielectric structure 451. The third conductive structure may include at least one third redistribution layer (RDL) 453 and at least one third via 452 formed concurrently and integrally. The third redistribution layer (RDL) 453 may be formed or disposed on the third dielectric layer, or may be embedded in the third dielectric structure 451. The third via 452 may be formed or disposed in the opening(s) 4511 to extend through the third dielectric layer, and may be electrically connected to the third redistribution layer (RDL) 453 and the first pillars 43. Meanwhile, the third dielectric structure 451 and the third conductive structure may collectively form a third redistribution structure 45 (e.g., a top redistribution structure) disposed on the top surface of the first encapsulant 41. The third redistribution layer (RDL) 453 may include a plurality of third pads exposed from a top surface of the third dielectric structure 45.

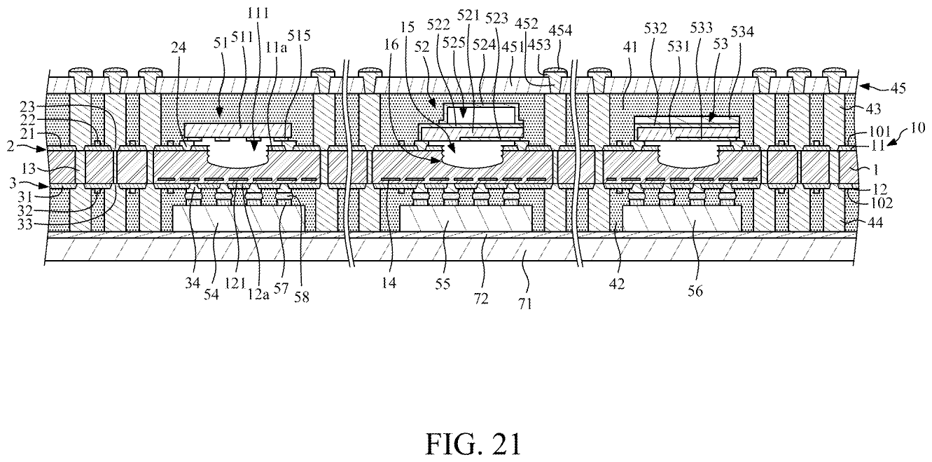

Referring to FIG. 21, a plurality of first solders 454 may be formed or disposed on the third pads of the third redistribution layer (RDL) 453 for external connection.

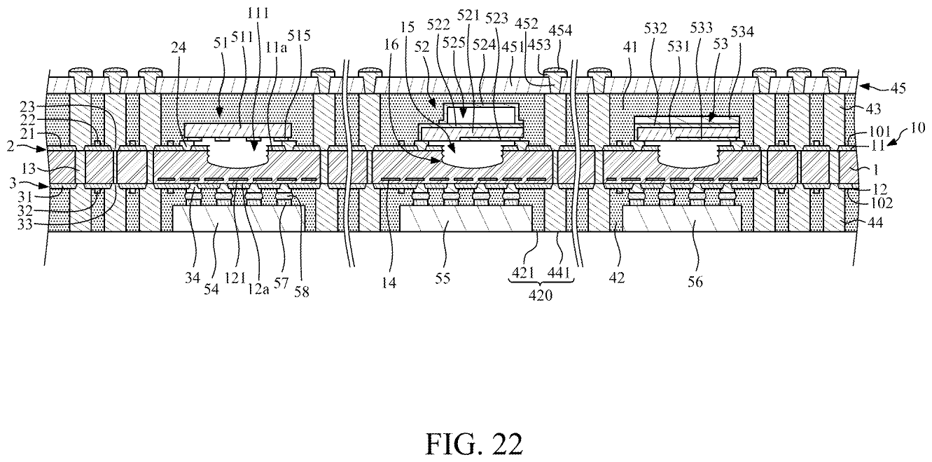

Referring to FIG. 22, the release layer 72 and the carrier 71 are removed.

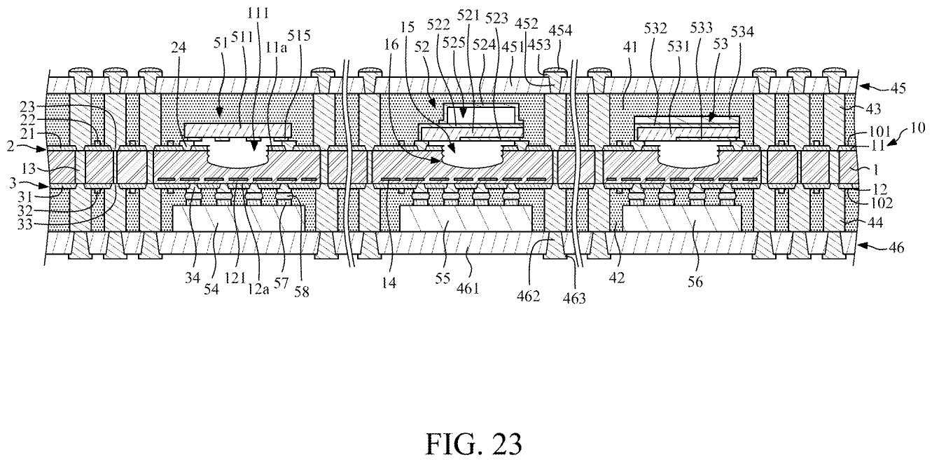

Referring to FIG. 23, a fourth redistribution structure 46 (e.g., a bottom redistribution structure) may be formed or disposed on the bottom surface 420 of the second encapsulant 42. In some embodiments, the fourth redistribution structure 46 may include a fourth dielectric structure 461 and a fourth conductive structure. The fourth dielectric structure 461 may include at least one fourth dielectric layer. The fourth conductive structure may include at least one fourth redistribution layer (RDL) 463 and at least one fourth via 462. The fourth redistribution layer (RDL) 463 may be disposed on the fourth dielectric layer, or may be embedded in the fourth dielectric structure 461. The fourth via 462 may extend through the fourth dielectric layer and may be electrically connected to the fourth redistribution layer (RDL) 463 and the second pillars 44. The fourth redistribution layer (RDL) 463 may include a plurality of fourth pads exposed from a bottom surface of the fourth dielectric structure 46.

Then, a plurality of second solders 464 may be formed or disposed on the fourth pads of the fourth redistribution layer (RDL) 463 for external connection. Then, a singualation process may be conducted so as to obtain the package structure 4 of FIG. 1.

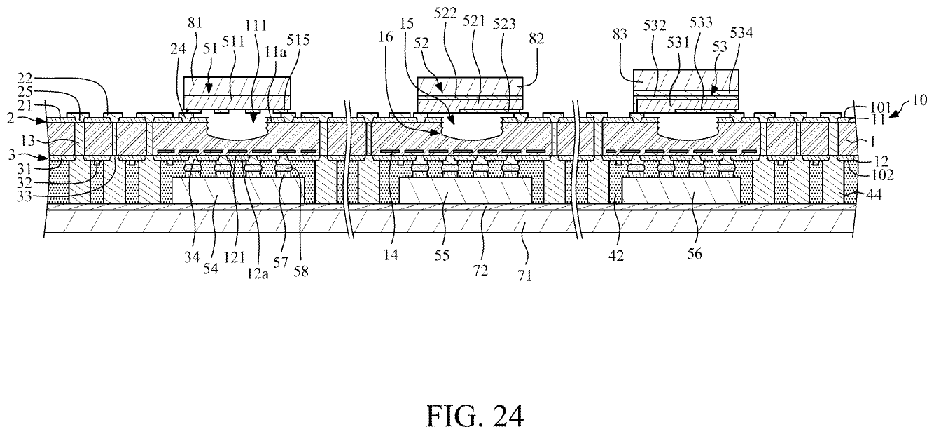

FIG. 24 through FIG. 34 illustrate an example of a method for manufacturing a package structure according to some embodiments of the present disclosure. In some embodiments, the method is for manufacturing a package structure such as the package structure 4a shown in FIG. 6. The initial several stages of the method corresponding to FIG. 24 through FIG. 34 are the same as, or at least similar to, the stages illustrated in FIG. 11 through FIG. 15. FIG. 24 depicts a stage subsequent to that depicted in FIG. 15.

Referring to FIG. 24, a first conductive structure 22 may be formed on or disposed on or disposed in the first dielectric layer. The first conductive structure 22 may include at least one first redistribution layer (RDL), at least one periphery protrusion pad 25 and at least one first protrusion pad 24. The first redistribution layer (RDL) may be disposed on the first dielectric layer, or may be embedded in the first dielectric structure 21. The periphery protrusion pad 25 may be disposed in the first opening 213 so as to extend through the first dielectric layer. The periphery protrusion pad 25 may be disposed around the first protrusion pad 24. The first protrusion pad 24 may be disposed in the second opening 214 so as to extend through the first dielectric layer, and may be exposed from a top surface of the first dielectric structure 21. Meanwhile, the first dielectric structure 21 and the first conductive structure 22 may collectively form a first redistribution structure 2 disposed on the first surface 11 of the semiconductor substrate 1. Further, the semiconductor substrate 1, the first redistribution structure 2 and the second redistribution structure 3 may collectively form a semiconductor substrate structure 10.

Then, an assembly of the piezoelectric material 511 and the first carrier 81 may be attached to or connected to the first protrusion pad 24. Thus, a first filter structure 51 may be formed, and may be electrically connected to the first redistribution structure 2 of the semiconductor substrate structure 10. Then, an assembly of the piezoelectric material 521 and the second carrier 82 may be attached to or connected to the first protrusion pad 24. Thus, a second filter structure 52 may be formed, and may be electrically connected to the first redistribution structure 2 of the semiconductor substrate structure 10. Then, an assembly of the piezoelectric material 531 and the third carrier 83 may be attached to or connected to the first protrusion pad 24. Thus, a third filter structure 53 may be formed, and may be electrically connected to the first redistribution structure 2 of the semiconductor substrate structure 10.

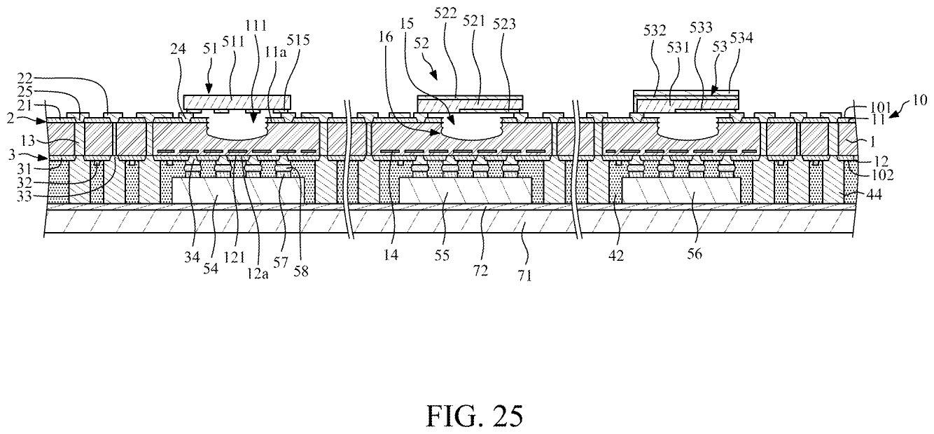

Referring to FIG. 25, the first carrier 81, the second carrier 82 and the third carrier 83 may be removed.

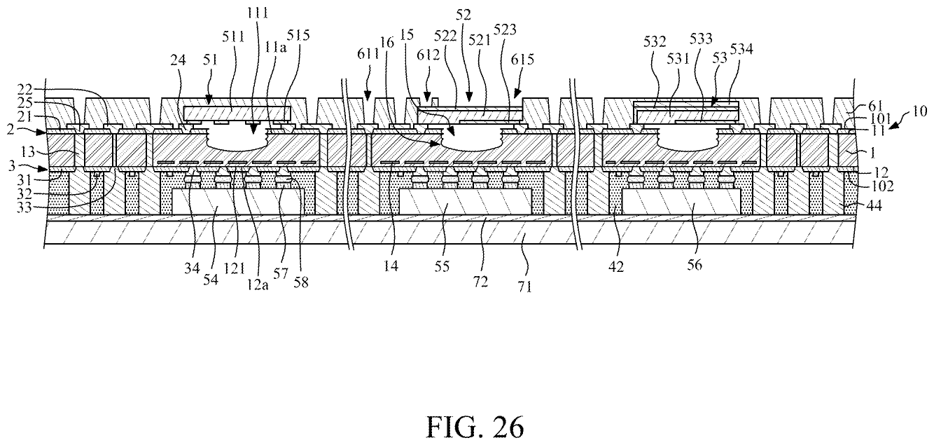

Referring to FIG. 26, a fifth dielectric layer 61 may be formed or disposed to cover the first redistribution structure 2, the first filter structure 51, the second filter structure 52 and the third filter structure 53. The fifth dielectric layer 61 may not extend into the recess portion 16 or the cavity 15. Then, at least one first opening 611, at least one second opening 612 and an accommodating hole 615 may be formed in the fifth dielectric layer 61. The first opening 611 may extend through the fifth dielectric layer 61 and expose the periphery protrusion pad 25. The second opening 612 may extend through a first portion of the fifth dielectric layer 61 that is disposed on a first portion of the first electrode 522 of the second filter structure 52 so as to expose the first portion of the first electrode 522 of the second filter structure 52. The accommodating hole 615 may extend through a second portion of the fifth dielectric layer 61 that is disposed on a second portion of the first electrode 522 of the second filter structure 52 so as to expose the second portion of the first electrode 522 of the second filter structure 52.

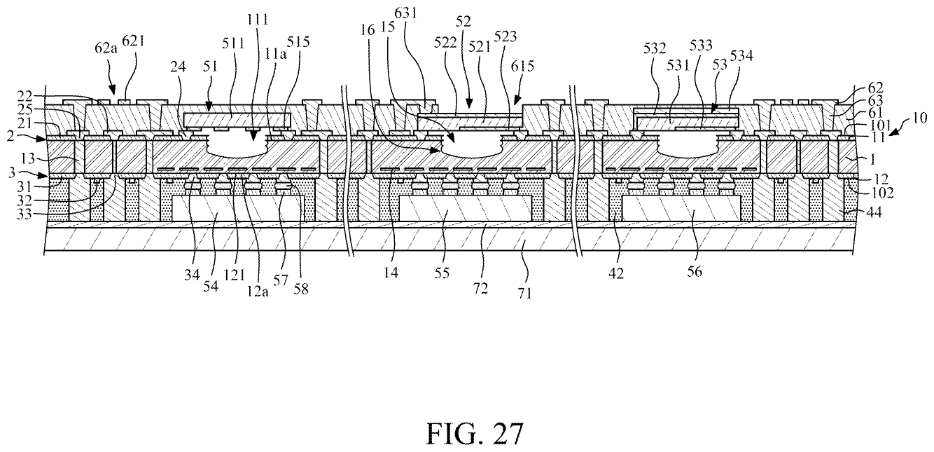

Referring to FIG. 27, a fifth conductive structure 62 may be formed or disposed on the top surface of the fifth dielectric layer 61. In some embodiments, the fifth conductive structure 62 may include a fifth redistribution layer (RDL) and at least one fifth via 63. The fifth redistribution layer (RDL) may be disposed on the fifth dielectric layer 61. The fifth via 63 may be formed or disposed in the first opening 611 so as to extend through the fifth dielectric layer 61. The fifth via 63 may be electrically connected to the fifth redistribution layer (RDL) of the fifth conductive structure 62 and the periphery protrusion pad 25 of the first redistribution structure 2. In addition, the fifth via 63 may include a shorter via 631 formed or disposed in the second opening 612. The shorter via 631 may extend through the first portion of the fifth dielectric layer 61 so as to electrically connect to the first electrode 522. In some embodiments, as shown in FIG. 6A, the fifth conductive structure 62 may include at least one integrated passive device (IPD) such as an inductor 621 disposed in a first IPD region 62a.

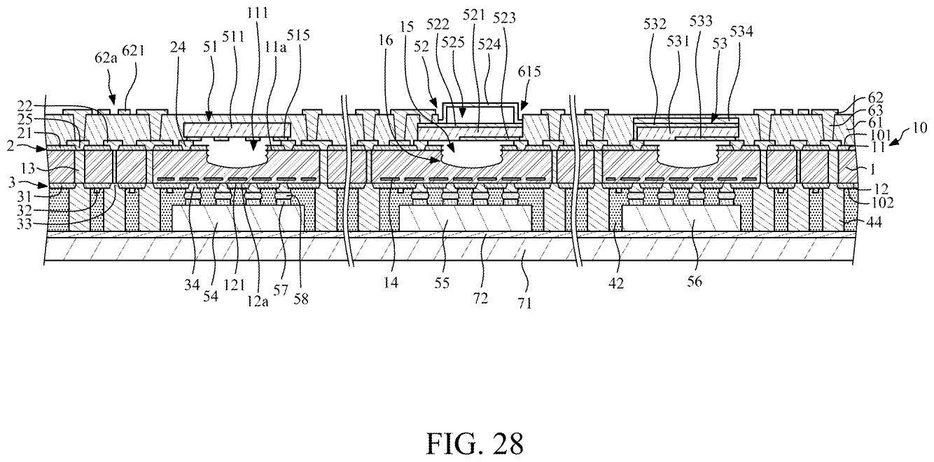

Referring to FIG. 28, a second acoustic impedance structure 524 (e.g., cap structure 524) may be placed or disposed in the accommodating hole 615. A lower portion of the second acoustic impedance structure 524 (e.g., cap structure 524) may be located in the accommodating hole 615 to contact or connect to the first electrode 522. An upper portion of the second acoustic impedance structure 524 (e.g., cap structure 524) may protrude from a top surface of the fifth dielectric layer 61.

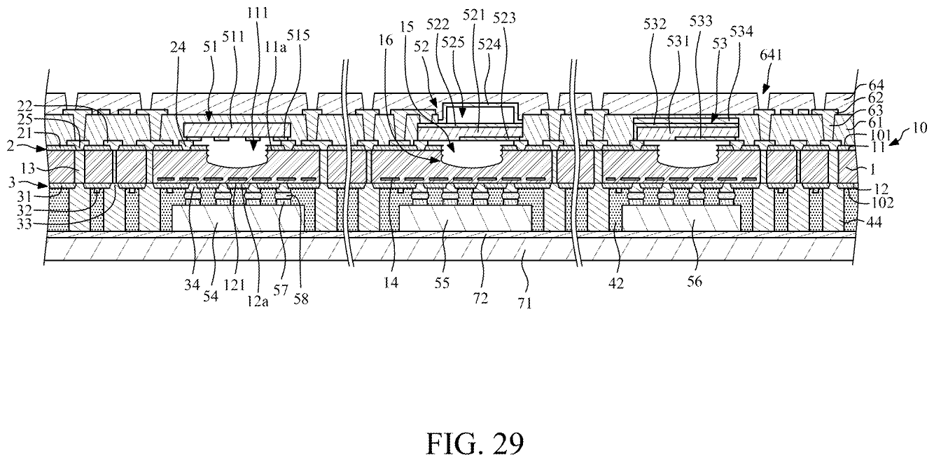

Referring to FIG. 29, a sixth dielectric layer 64 may be formed or disposed to cover the fifth dielectric layer 61 and the fifth conductive structure 62. The sixth dielectric layer 64 may further cover the upper portion of the second acoustic impedance structure 524 (e.g., cap structure 524) and may extend into the accommodating hole 615 of the fifth dielectric layer 61. Then, a plurality of openings 641 may be formed to extend through the sixth dielectric layer 64 and to expose a portion of the fifth conductive structure 62.

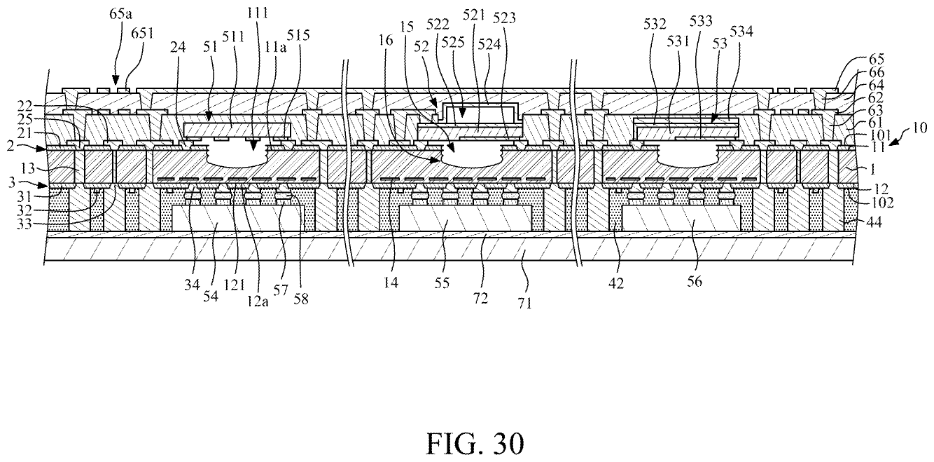

Referring to FIG. 30, a sixth conductive structure 65 may be formed or disposed on the top surface of the sixth dielectric layer 64. In some embodiments, the sixth conductive structure 65 may include a sixth redistribution layer (RDL) and at least one sixth via 66. The sixth redistribution layer (RDL) may be disposed on the sixth dielectric layer 64. The sixth via 66 may be formed or disposed in the opening 641 so as to extend through the sixth dielectric layer 64. The sixth via 66 may be electrically connected to the sixth redistribution layer (RDL) of the sixth conductive structure 65 and the fifth redistribution layer (RDL) of the fifth conductive structure 62. In some embodiments, the sixth conductive structure 65 may include at least one integrated passive device (IPD) such as an inductor 651 disposed in a second IPD region 65a.

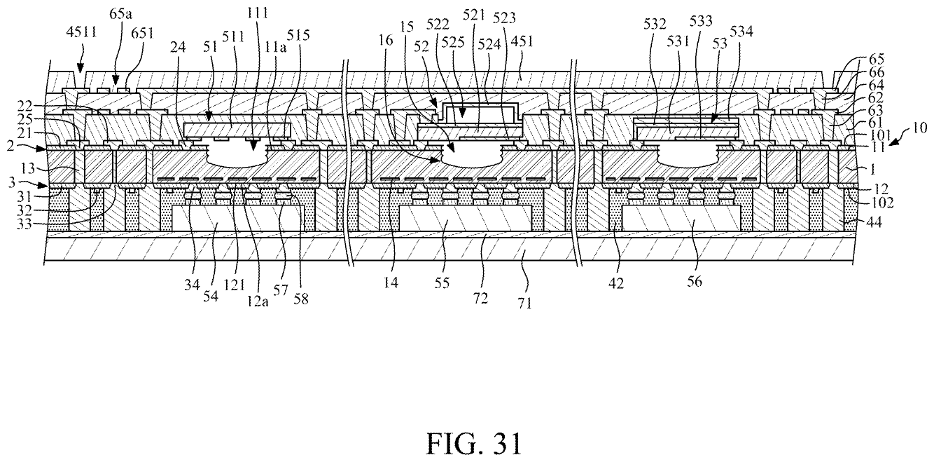

Referring to FIG. 31, a third dielectric structure 451 may be formed or disposed to cover the sixth dielectric layer 64 and the sixth conductive structure 65. The third dielectric structure 451 may include at least one third dielectric layer. Then, a plurality of openings 4511 may be formed in the third dielectric structure 451 to expose a portion of the sixth conductive structure 65.

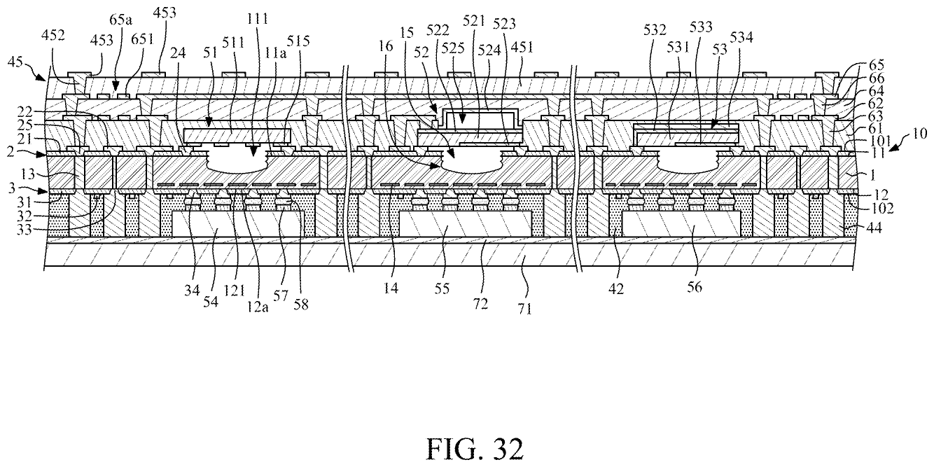

Referring to FIG. 32, a third conductive structure may be formed on or formed in the third dielectric structure 451. The third conductive structure may include at least one third redistribution layer (RDL) 453 and at least one third via 452 formed concurrently and integrally. The third redistribution layer (RDL) 453 may be formed or disposed on the third dielectric layer, or may be embedded in the third dielectric structure 451. The third via 452 may be formed or disposed in the opening(s) 4511 to extend through the third dielectric layer. The third via 452 may be electrically connected to the third redistribution layer (RDL) 453 and the sixth conductive structure 65. Meanwhile, the third dielectric structure 451 and the third conductive structure may collectively form a third redistribution structure 45 (e.g., a top redistribution structure). The third redistribution layer (RDL) 453 may include a plurality of third pads exposed from a top surface of the third dielectric structure 45.

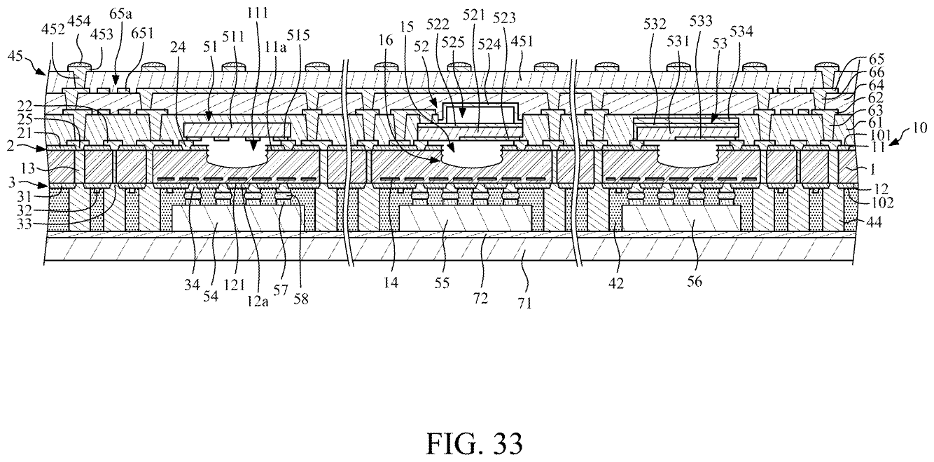

Referring to FIG. 33, a plurality of first solders 454 may be formed or disposed on the third pads of the third redistribution layer (RDL) 453 for external connection.

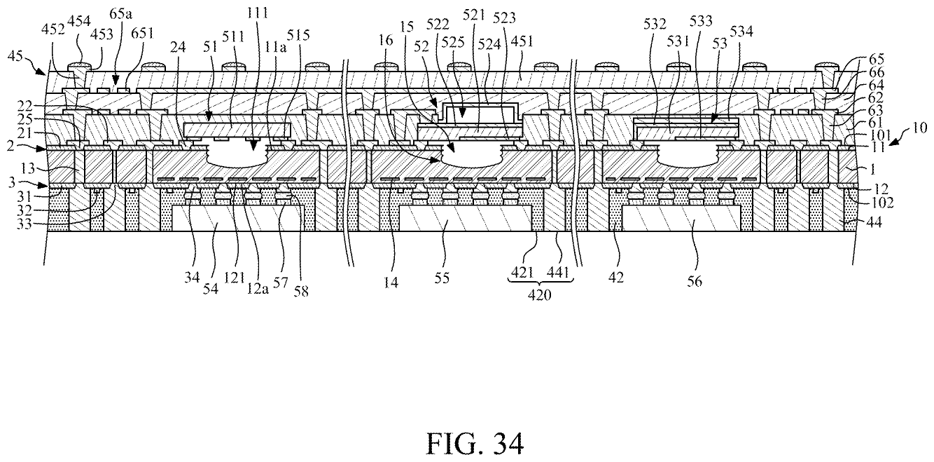

Referring to FIG. 34, the release layer 72 and the carrier 71 are removed.

Then, a fourth redistribution structure 46 (e.g., a bottom redistribution structure) may be formed or disposed on the bottom surface 420 of the second encapsulant 42. Then, a plurality of second solders 464 may be formed or disposed on the fourth pads of the fourth redistribution layer (RDL) 463 for external connection. Then, a singualation process may be conducted so as to obtain the package structure 4a of FIG. 6.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to 1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A semiconductor substrate including:
a first surface including a filtering region; and
a second surface opposite to the first surface and including an amplifying region.

2. The semiconductor substrate of claim 1, further including an active circuit layer disposed in the semiconductor substrate.

3. The semiconductor substrate of claim 2, wherein the active circuit layer is closer to the amplifying region than to the filtering region.

4. The semiconductor substrate of claim 1, further includes a cavity located adjacent to the filtering region.

5. The semiconductor substrate of claim 4, wherein a bottom end of the cavity is closer to the second surface than to the first surface.

6. The semiconductor substrate of claim 4, further including a through via extending through the semiconductor substrate and configured to transmit a signal from the filtering region to the amplifying region.

7. The semiconductor substrate of claim 4, further including an inner lateral surface defining the cavity, wherein the inner lateral surface includes at least one curved surface.

8. The semiconductor substrate of claim 7, wherein the inner lateral surface includes a plurality of curved surfaces stacked along a direction nonparallel with the first surface.

9. A package structure, comprising:
a semiconductor substrate having a first surface and a second surface opposite to the first surface;
a filter structure disposed adjacent to the first surface; and
an amplifier disposed under the second surface.

10. The package structure of claim 9, wherein the filter structure includes a first acoustic impedance structure.

11. The package structure of claim 10, wherein the first acoustic impedance structure includes a cavity in the semiconductor substrate.

12. The package structure of claim 11, wherein the semiconductor substrate includes an active circuit layer located under the cavity.

13. The package structure of claim 10, wherein the filter structure further includes a main body configured to generate an acoustic wave, a boundary is formed between the main body and the first acoustic impedance structure, and a first acoustic reflectivity of the acoustic wave at the boundary is greater than 0.5.

14. The package structure of claim 13, wherein the first acoustic reflectivity is substantially equal to 1.

15. The package structure of claim 9, wherein the filter structure includes a piezoelectric material.

16. The package structure of claim 15, further comprising an encapsulant encapsulating the filter structure, and the piezoelectric material is disposed between the encapsulant and the first acoustic impedance structure.

17. A package structure, comprising:
a semiconductor substrate defining a cavity; and
a piezoelectric material disposed over the cavity of the semiconductor substrate, wherein the cavity is coupled to the piezoelectric material and configured to reflect an acoustic wave.

18. The package structure of claim 17, wherein the semiconductor substrate has a top surface and a bottom surface opposite to the top surface, the piezoelectric material is disposed over the top surface of the semiconductor substrate, and the cavity is recessed from the top surface of the semiconductor substrate.

19. The package structure of claim 18, wherein the piezoelectric material is electrically connected to the semiconductor substrate through a first electrode and a second electrode, a portion of the first electrode is disposed by a first side of the cavity, and a portion of the second electrode is disposed by a second side of the cavity opposite to the first side.

20. The package structure of claim 17, wherein the cavity and the piezoelectric material constitute a filter.
